(19) United States
(12) Patent Application Publication
(10) Pub. No.: US 2023/0393202 A1
(43) Pub. Date: Dec. 7, 2023

(54) BATTERY CHARACTERISTIC REPRODUCTION DEVICE, BATTERY CHARACTERISTIC REPRODUCTION METHOD, AND STORAGE MEDIUM

(71) Applicant: HONDA MOTOR CO., LTD., Tokyo (JP)

(72) Inventor: Yasumichi Onuki, Wako-shi (JP)

(21) Appl. No.: 18/203,670

(22) Filed: May 31, 2023

(30) Foreign Application Priority Data
Jun. 7, 2022 (JP) 2022-092277

(51) Int. Cl. G01R 31/367; G01R 31/389; B60L 3/00; B60L 58/10

(52) U.S. Cl. CPC G01R 31/367; G01R 31/389; B60L 3/0046; B60L 58/10

(57) ABSTRACT

A battery characteristic reproduction device includes a processor configured to execute computer-readable instructions to perform. The processor is configured to extracting a smallest resistance value included in frequency characteristics of measured impedance of a battery, extracting a difference between a resistance value measured at a measurement point and a resistance value measured at an adjacent measurement point for each measurement point of each frequency included in the frequency characteristics, and reproducing the frequency characteristics of the impedance in the battery by configuring the smallest resistance value extracted as a first resistance component, configuring an equivalent circuit of the battery including the difference between the resistance values extracted as a second resistance component for each measurement point, and connecting the first resistance component and the equivalent circuit for each measurement point in series.

### CROSS-REFERENCE TO RELATED APPLICATION

Priority is claimed on Japanese Patent Application No. 2022-092277, filed Jun. 7, 2022, the content of which is incorporated herein by reference.

### BACKGROUND OF THE INVENTION

### Field of the Invention

The present invention relates to a battery characteristic reproduction device, a battery characteristic reproduction method, and a storage medium.

### Description of Related Art

Efforts are underway to reduce adverse effects on the global environment (for example, reduction of NOₓ and SOₓ or reduction of CO₂). Thus, in recent years, from the viewpoint of improving the global environment, for reduction of CO₂, there has been growing interest in at least electric vehicles that are able to run on electric motors driven by power supplied by batteries (secondary batteries) such as, for example, a hybrid electric vehicle (HEV) and a plug-in hybrid electric vehicle (PHEV). The use of a lithium-ion secondary battery as a battery for in-vehicle use is being studied. In these electric vehicles, it is important to bring out the full performance of the secondary battery. Thus, for example, it is significantly useful to estimate the internal state of a secondary battery from a relationship between SOC or a temperature and a deterioration state and the like. When the state of the secondary battery can be estimated, the response, behavior, and the like when a current is applied to the secondary battery can be calculated. For example, when the electric motor of an electric vehicle is driven on the basis of a calculation result, for example, it is possible to derive a current-carrying pattern that is within an upper limit value and a lower limit value of the voltage of the secondary battery.

In relation to this, for example, Japanese Unexamined Patent Application, First Publication No. 2009-097878 discloses technology related to a method of deriving an equivalent circuit of a secondary battery. In the deriving method disclosed in Japanese Unexamined Patent Application, First Publication No. 2009-097878, a plurality of equivalent circuits of the secondary battery are connected, such that the frequency characteristics of internal impedance of a lithium-ion battery are measured in an alternating current (AC) impedance method and an impedance model in which an equivalent circuit representing the electrochemical impedance of the positive electrode of the lithium-ion battery and an equivalent circuit representing the electrochemical impedance of the negative electrode are connected in multiple stages is used in a result of measuring frequency characteristics of the internal impedance. In the deriving method disclosed in Japanese Unexamined Patent Application, First Publication No. 2009-097878, an optimum value of a parameter of each element constituting the impedance model is determined so that calculation results of the frequency characteristics of the impedance in the impedance model match.

### SUMMARY OF THE INVENTION

However, the actual impedance characteristic of the secondary battery is not a characteristic that can be expressed in a simple shape. Thus, in the related art, it may be necessary to iteratively adjust the pattern of an impedance model or change the circuit configuration of each equivalent circuit so that the calculation result of the frequency characteristics of the impedance in the impedance model matches the actual frequency characteristics of the impedance in the secondary battery, and this work may become complicated.

The present invention has been made on the basis of the recognition of the above-described problems and an objective of the present invention is to provide a battery characteristic reproduction device, a battery characteristic reproduction method, and a storage medium capable of deriving a current-carrying pattern capable of improving the efficiency of energy by configuring an equivalent circuit for reproducing characteristics of a secondary battery on the basis of measured impedance characteristics of the secondary battery.

A battery characteristic reproduction device, a battery characteristic reproduction method, and a storage medium according to the present invention adopt the following configurations.
(1): According to an aspect of the present invention, there is provided a battery characteristic reproduction device including a processor configured to execute computer-readable instructions to perform: extracting a smallest resistance value included in frequency characteristics of measured impedance of a battery; extracting a difference between a resistance value measured at a measurement point and a resistance value measured at an adjacent measurement point for each measurement point of each frequency included in the frequency characteristics; and reproducing the frequency characteristics of the impedance in the battery by configuring the smallest resistance value extracted as a first resistance component, configuring an equivalent circuit of the battery including the difference between the resistance values extracted as a second resistance component for each measurement point, and connecting the first resistance component and the equivalent circuit for each measurement point in series.
(2): In the above-described aspect (1), the extracting the difference between the resistance values comprises: extracting the difference between the resistance values in a band of a frequency lower than a frequency of a measurement point at which the smallest resistance value has been extracted, and extracting the difference between the resistance values in a band of a frequency higher than the frequency of the measurement point at which the smallest resistance value has been extracted, and the reproducing the frequency characteristics of the impedance in the battery comprises making the equivalent circuit including the difference between the resistance values extracted by the low-frequency band as the second resistance component different from the equivalent circuit including the difference between the resistance values extracted by the high-frequency band as the second resistance component.
(3): In the above-described aspect (2), the equivalent circuit including the difference between the resistance values extracted by the low-frequency band as the second resistance component has a configuration in which a series circuit in which the second resistance component is connected in series with an impedance component representing a frequency of the measurement point is connected in parallel to a capacitance component representing the frequency of the measurement point, and the equivalent circuit including the difference between the resistance values extracted by the high-frequency band as the second resistance component has a configuration in which a series circuit in which the second resistance component is connected in series with the capacitance component representing the frequency of the measurement point is connected in parallel to the impedance component representing the frequency of the measurement point.
(4): In the above-described aspect (3), the processor is configured to execute the computer-readable instructions to perform: extracting a high-frequency-side reactance component in the battery included in the frequency characteristics, and reproducing the frequency characteristics of the impedance in the battery by further connecting an inductor having inductance representing the high-frequency-side reactance component in series.
(5): In the above-described aspect (3), the processor is configured to execute the computer-readable instructions to perform: extracting a low-frequency-side reactance component in the battery included in the frequency characteristics, and reproducing the frequency characteristics of the impedance in the battery by further connecting a capacitor having capacitance representing the low-frequency-side reactance component in series.
(6): According to an aspect of the present invention, there is provided a battery characteristic reproduction method including: extracting, by a computer, a smallest resistance value included in frequency characteristics of measured impedance of a battery; extracting, by the computer, a difference between a resistance value measured at a measurement point and a resistance value measured at an adjacent measurement point for each measurement point of each frequency included in the frequency characteristics; and reproducing, by the computer, the frequency characteristics of the impedance in the battery by configuring the extracted smallest resistance value as a first resistance component, configuring an equivalent circuit of the battery including the extracted difference between the resistance values as a second resistance component for each measurement point, and connecting the first resistance component and the equivalent circuit for each measurement point in series.
(7): According to an aspect of the present invention, there is provided a non-transitory computer-readable storage medium storing a program for causing a computer to: extract a smallest resistance value included in frequency characteristics of measured impedance of a battery; extract a difference between a resistance value measured at a measurement point and a resistance value measured at an adjacent measurement point for each measurement point of each frequency included in the frequency characteristics; and reproduce the frequency characteristics of the impedance in the battery by configuring the extracted smallest resistance value as a first resistance component, configuring an equivalent circuit of the battery including the extracted difference between the resistance values as a second resistance component for each measurement point, and connecting the first resistance component and the equivalent circuit for each measurement point in series.

According to the above-described aspects (1) to (7), it is possible to derive a current-carrying pattern capable of improving the efficiency of energy by configuring an equivalent circuit for reproducing characteristics of a secondary battery on the basis of measured impedance characteristics of the secondary battery.

### BRIEF DESCRIPTION OF THE DRAWINGS

FIG. 1 is a diagram showing an example of a configuration of a battery characteristic reproduction device according to an embodiment.

FIG. 2 is a diagram showing an example of battery characteristic data input to the battery characteristic reproduction device of the embodiment.

FIG. 3 is a diagram showing a method of configuring an equivalent reproduction circuit in an equivalent circuit configurator provided in the battery characteristic reproduction device of the embodiment.

FIG. 4 is a diagram showing frequency characteristics of an equivalent circuit in a low-frequency band configured by the equivalent circuit configurator according to the embodiment.

FIG. 5 is a diagram showing the difference between frequency characteristics when a constant is changed in the equivalent circuit in the low-frequency band according to the embodiment.

FIG. 6 is a diagram showing frequency characteristics of an equivalent circuit in a high-frequency band configured by the equivalent circuit configurator according to the embodiment.

FIG. 7 is a diagram showing the difference between frequency characteristics when a constant is changed in the equivalent circuit in the high-frequency band according to the embodiment.

FIG. 8 is a diagram showing an example of a configuration of an equivalent reproduction circuit configured by the battery characteristic reproduction device of the embodiment and its characteristics.

FIG. 9 is a diagram showing a matching degree of impedance characteristics of the equivalent reproduction circuit configured by the battery characteristic reproduction device of the embodiment.

FIG. 10 is a diagram showing an example of characteristics of a reactance component in the equivalent reproduction circuit configured by the battery characteristic reproduction device of the embodiment.

FIG. 11 is a diagram showing an example of frequency characteristics of the reactance component in the equivalent reproduction circuit configured by the battery characteristic reproduction device of the embodiment.

FIG. 12 is a diagram showing an example of a configuration of the equivalent reproduction circuit configured by the battery characteristic reproduction device of the embodiment and its characteristics.

FIG. 13 is a diagram showing an example of impedance characteristics of the equivalent reproduction circuit configured by the battery characteristic reproduction device of the embodiment.

FIG. 14 is a diagram showing an example of a matching degree of impedance characteristics of the equivalent reproduction circuit configured by the battery characteristic reproduction device of the embodiment.

FIG. 15 is a diagram showing an example of characteristics of a reactance component in the equivalent reproduction circuit configured by the battery characteristic reproduction device of the embodiment.

FIG. 16 is a diagram showing an example of a configuration of the equivalent reproduction circuit configured by the battery characteristic reproduction device of the embodiment and its characteristics.

FIG. 17 is a diagram showing an example of a configuration of the equivalent reproduction circuit configured by the battery characteristic reproduction device of the embodiment and its characteristics.

FIG. 18 is a diagram showing an example of a matching degree of impedance characteristics of the equivalent reproduction circuit configured by the battery characteristic reproduction device of the embodiment.

FIG. 19 is a diagram showing an example of the impedance characteristics of the equivalent reproduction circuit configured by the battery characteristic reproduction device of the embodiment.

FIG. 20 is a diagram showing an example of a more detailed configuration of the equivalent reproduction circuit configured by the battery characteristic reproduction device of the embodiment.

FIG. 21 is a flowchart showing an example of a flow of a process executed when the equivalent reproduction circuit is configured in the battery characteristic reproduction device of the embodiment.

FIG. 22 is a diagram showing an example of a case where a response of a battery is calculated using the equivalent reproduction circuit configured by the battery characteristic reproduction device of the embodiment.

### DETAILED DESCRIPTION OF THE INVENTION

Hereinafter, embodiments of a battery characteristic reproduction device, a battery characteristic reproduction method, and a storage medium of the present invention will be described with reference to the drawings. As used throughout this disclosure, the singular forms “a,” “an,” and “the” include a plurality of references unless the context clearly dictates otherwise.

### [Configuration of Battery Characteristic Reproduction Device]

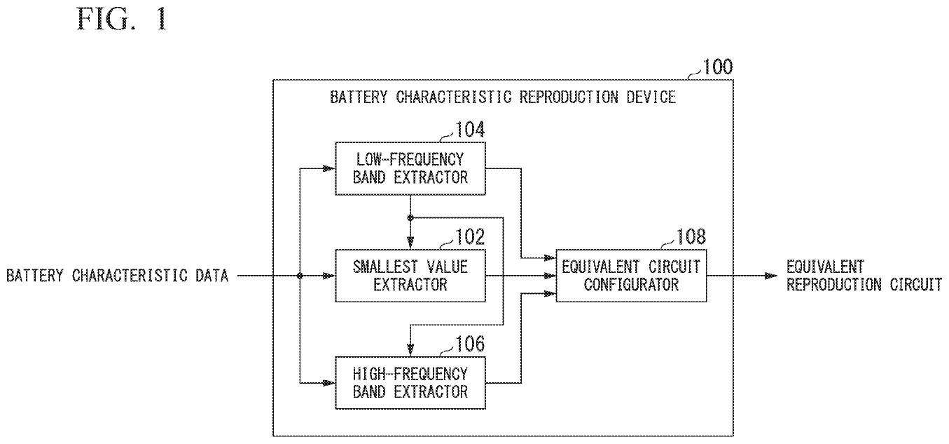

FIG. 1 is a diagram showing an example of a configuration of a battery characteristic reproduction device according to the embodiment. The battery characteristic reproduction device 100 includes, for example, a smallest value extractor 102, a low-frequency band extractor 104, a high-frequency band extractor 106, and an equivalent circuit configurator 108.

The battery characteristic reproduction device 100 or these constituent elements provided in the battery characteristic reproduction device 100 operate, for example, when a hardware processor such as a central processing unit (CPU) executes a program (software). The battery characteristic reproduction device 100 or these constituent elements provided in the battery characteristic reproduction device 100 may be implemented by hardware (including a circuit; circuitry) such as a large-scale integration (LSI) circuit, an application specific integrated circuit (ASIC), a field-programmable gate array (FPGA), or a graphics processing unit (GPU) or may be implemented by software and hardware in cooperation. The battery characteristic reproduction device 100 or these constituent elements provided in the battery characteristic reproduction device 100 may be implemented using functions of the constituent elements by a dedicated LSI. The program may be pre-stored in a storage device (a storage device including a non-transitory storage medium) such as a hard disk drive (HDD) or a flash memory provided in the battery characteristic reproduction device 100 or may be stored in a removable storage medium (a non-transitory storage medium) such as a DVD or a CD-ROM and installed in the HDD or the flash memory provided in the battery characteristic reproduction device 100 when the storage medium is mounted in the drive device provided in the battery characteristic reproduction device 100.

The battery characteristic reproduction device 100 constitutes an equivalent circuit representing the impedance characteristics of the battery on the basis of the input battery characteristic data. The battery characteristic data is characteristic data representing impedance characteristics inside of the battery measured by, for example, a measurer for measuring impedance representing an index of the ease of a flow of an alternating current (AC) inside of the battery or the like such as an impedance analyzer. That is, the battery characteristic reproduction device 100 configures an equivalent circuit (hereinafter referred to as an “equivalent reproduction circuit”) for reproducing the input battery characteristic data. The battery characteristic reproduction device 100 outputs information representing the configured equivalent reproduction circuit. The equivalent reproduction circuit can be used to calculate a response, behavior, and the like when a current is applied to the battery by arbitrarily setting parameters when a current is applied to the battery. For example, when the battery is mounted in a vehicle such as an electric vehicle, it is possible to derive a current-carrying pattern that is within the upper limit value and the lower limit value of a voltage of the battery by setting a parameter representing a current-carrying pattern when the electric motor is driven in the equivalent reproduction circuit of the battery.

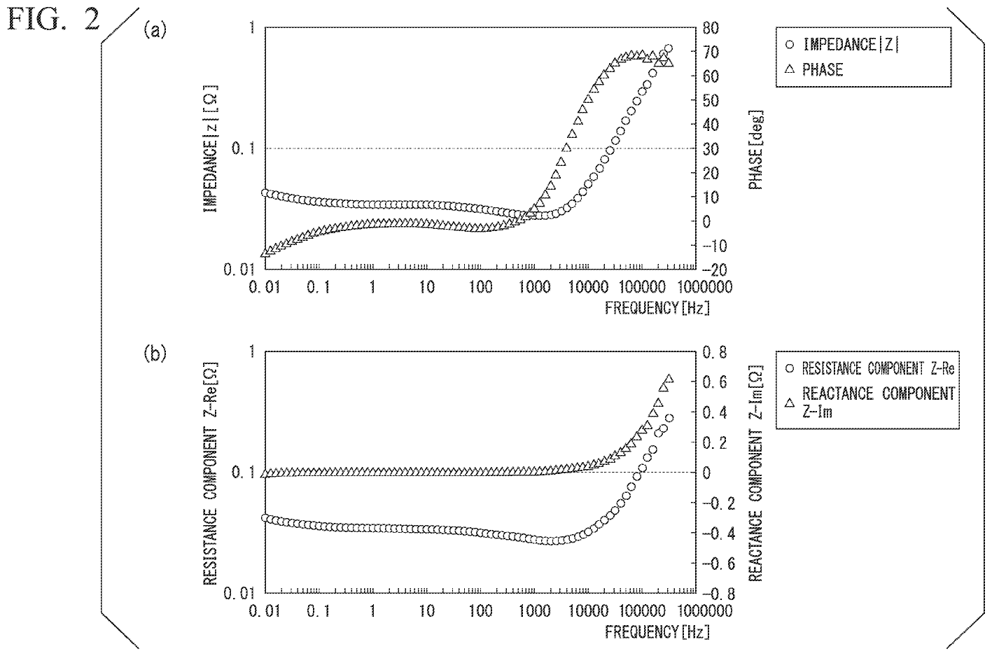

FIG. 2 is a diagram showing an example of battery characteristic data input to the battery characteristic reproduction device 100 of the embodiment. The battery characteristic data shown in FIG. 2 is data obtained by, for example, an impedance analyzer or the like measuring current impedance characteristics of a target battery constituting the equivalent reproduction circuit. The battery characteristic data shown in FIG. 2 is, for example, impedance characteristics of a cylindrical battery. (a) of FIG. 2 shows impedance |z| (an absolute value) included in the measured impedance characteristics and a phase in a Bode plot. (b) of FIG. 2 illustrates frequency characteristics shown by dividing data identical to impedance |z| shown in (a) of FIG. 2 into a real part (a resistance component Z-Re) and an imaginary part (a reactance component Z-Im). In general, it is known that there is a minimum point (a point where the resistance value is a smallest value) in the characteristics of the resistance component Z-Re in the impedance |z| of the battery. In the example shown in (b) of FIG. 2, the minimum point is around 4 [kHz].

The smallest value extractor 102 extracts a frequency measurement point serving as a minimum point (hereinafter referred to as a “minimum measurement point”) associated with the characteristics of the resistance component Z-Re as shown in (b) of FIG. 2 on the basis of the input battery characteristic data. The smallest value extractor 102 sets a resistance value (a minimum resistance value) of the resistance component Z-Re at the extracted minimum measurement point as a resistance value Rs, sets an angular frequency of the minimum measurement point as an angular frequency ω0, and outputs the resistance value Rs and the angular frequency ω0 to the equivalent circuit configurator 108. The smallest value extractor 102 outputs information (which may be information of angular frequency ω0) representing the extracted minimum measurement point to the low-frequency band extractor 104 and the high-frequency band extractor 106. The resistance value Rs is an example of a “first resistance component.”

The low-frequency band extractor 104 extracts a resistance value of the resistance component Z-Re at each measurement point located in a lower-frequency band than the minimum measurement point output by the smallest value extractor 102 in input battery characteristic data. The low-frequency band extractor 104 calculates the difference between resistance values of two adjacent measurement points at each extracted measurement point. Further, the low-frequency band extractor 104 calculates angular frequencies representing two adjacent measurement points for which a resistance value difference has been calculated. The low-frequency band extractor 104 calculates differences between resistance values equal in number to measurement points located in a low-frequency band in the input battery characteristic data and corresponding angular frequencies. At this time, the low-frequency band extractor 104 may set the angular frequency of one of the two adjacent measurement points as the angular frequency corresponding to the resistance value difference or may set an intermediate value (for example, an average value) of angular frequencies of two adjacent measurement points as the angular frequency corresponding to the resistance value difference. The low-frequency band extractor 104 sets the difference between the calculated resistance values as a resistance value Rn, sets the angular frequency corresponding to each resistance value Rn as an angular frequency ton, and outputs the resistance value Rn and the angular frequency ωn to the equivalent circuit configurator 108.

The high-frequency band extractor 106 extracts a resistance value of the resistance component Z-Re at each measurement point located in a higher-frequency band than the minimum measurement point output by the smallest value extractor 102 in the input battery characteristic data. The high-frequency band extractor 106 calculates the difference between resistance values of two adjacent measurement points at each extracted measurement point. Further, the high-frequency band extractor 106 calculates angular frequencies representing two adjacent measurement points for which the resistance value difference has been calculated. The high-frequency band extractor 106 calculates differences between resistance values equal in number to measurement points located in a higher-frequency band in the input battery characteristic data and a corresponding angular frequency. At this time, the high-frequency band extractor 106 may set the angular frequency of one of the two adjacent measurement points as the angular frequency corresponding to the resistance value difference or may set an intermediate value (for example, an average value) of angular frequencies of two adjacent measurement points as the angular frequency corresponding to the resistance value difference. The high-frequency band extractor 106 sets the difference between the calculated resistance values as a resistance value Rm, sets the angular frequency corresponding to each resistance value Rm as an angular frequency ωm, and outputs the resistance value Rm and the angular frequency ωm to the equivalent circuit configurator 108.

A configuration obtained by combining the low-frequency band extractor 104 and the high-frequency band extractor 106 is an example of a “difference extractor.” A resistance value obtained by combining the resistance value Rn and the resistance value Rm is an example of a “second resistance component.”

The equivalent circuit configurator 108 configures an equivalent reproduction circuit for reproducing impedance characteristics of a battery represented by input battery characteristic data on the basis of the resistance value Rs output by the smallest value extractor 102, the resistance value Rn and the angular frequency ωn output by the low-frequency band extractor 104, and the resistance value Rm and angular frequency ωm output by the high-frequency band extractor 106. The equivalent circuit configurator 108 is an example of a “characteristic reproducer.”

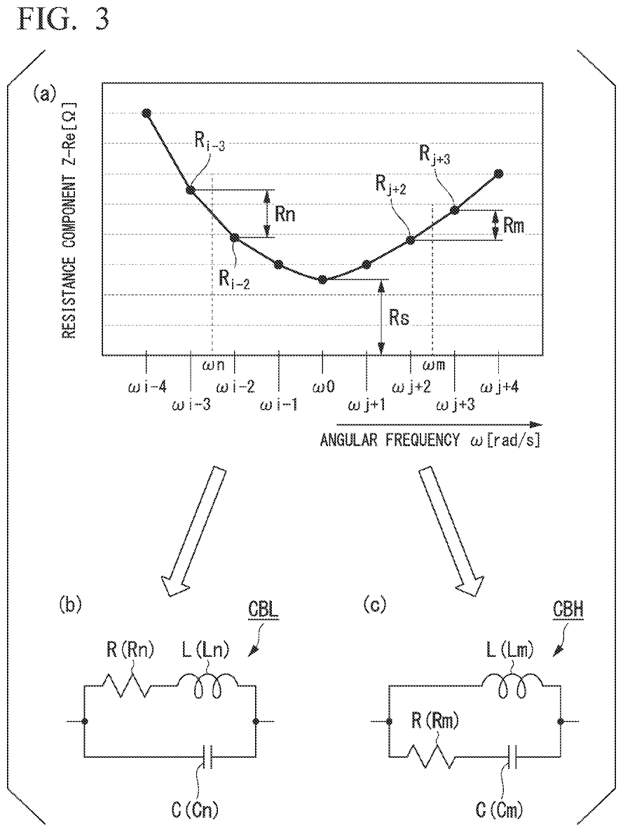

Here, an example of a method in which the equivalent circuit configurator 108 configures an equivalent reproduction circuit will be described. FIG. 3 is a diagram showing a method of configuring an equivalent reproduction circuit in the equivalent circuit configurator 108 provided in the battery characteristic reproduction device 100 of the embodiment. In (a) of FIG. 3, an example of the characteristics of the resistance component Z-Re near the minimum measurement point is shown. In (a) of FIG. 3, each angular frequency ω is a measurement point. In (b) of FIG. 3, an example of a block (hereinafter referred to as “circuit block”) CBL of a single-stage equivalent circuit provided as an equivalent circuit corresponding to a measurement point having a lower-frequency band than a minimum measurement point when the equivalent circuit configurator 108 configures an equivalent reproduction circuit is shown. In (c) of FIG. 3, an example of a block (hereinafter referred to as “circuit block”) CBH of a single-stage equivalent circuit provided as an equivalent circuit corresponding to a measurement point having a higher-frequency band than a minimum measurement point when the equivalent circuit configurator 108 configures an equivalent reproduction circuit is shown.

In (a) of FIG. 3, an example of a case where the smallest value extractor 102 extracts a resistance value Rs at a minimum measurement point (an angular frequency ω0) on the basis of characteristics of the resistance component Z-Re is shown. The equivalent circuit configurator 108 configures a resistor R0 having the resistance value Rs as an equivalent circuit corresponding to the resistance value Rs output by the smallest value extractor 102.

The low-frequency band extractor 104 extracts a resistance value Rᵢ at each measurement point (angular frequency on) located in a lower-frequency band than the minimum measurement point on the basis of the characteristics of the resistance component Z-Re shown in (a) of FIG. 3. The low-frequency band extractor 104 extracts, for example, a resistance value Rᵢ at an angular frequency ωi and a resistance value Rᵢ₋₁ at an angular frequency ωi−1 that is a measurement point adjacent to a side of a frequency lower than the angular frequency ωi. The low-frequency band extractor 104 calculates a resistance value Rn which is the difference between the extracted resistance values of the two measurement points according to the following Eq. (1).

Rn=Rᵢ₋₁−Rᵢ . . . (1)

In (a) of FIG. 3, an example in which the low-frequency band extractor 104 calculates the difference between the resistance value Rᵢ₋₂ at the angular frequency ωi−2 and the resistance value Rᵢ₋₃ at the angular frequency ωi−3 as the resistance value Rn is shown. Further, in (a) of FIG. 3, an example in which the low-frequency band extractor 104 sets the angular frequency ω at the center of the angular frequency ωi−2 and the angular frequency ωi−3 as an angular frequency ωn corresponding to the calculated resistance value Rn is shown.

The equivalent circuit configurator 108 calculates capacitance Cn according to the following Eq. (2) on the basis of the resistance value Rn and the angular frequency con output by the low-frequency band extractor 104 and calculates the inductance Ln according to the following Eq. (3).

Cn=√2/(Rnωn) . . . (2)

Ln=Rn/((√2)ωn) (3)

Also, as shown in (b) of FIG. 3, the equivalent circuit configurator 108 configures the circuit block CBL in which a resistor R with a resistance value Rn and an inductor L with inductance Ln are connected in series and a capacitor C of capacitance Cn is connected in parallel to this series circuit as an equivalent circuit corresponding to the resistance value Rn and the angular frequency ωn output by the low-frequency band extractor 104. That is, the equivalent circuit configurator 108 configures an equivalent reproduction circuit including the circuit block CBL shown in (b) of FIG. 3 as an equivalent circuit for reproducing battery characteristics in a lower-frequency band than the minimum measurement point. The equivalent circuit configurator 108 provides the circuit block CBL shown in (b) of FIG. 3 for each measurement point located in a lower-frequency band than the minimum measurement point. However, the values of the resistance value Rn, the capacitance Cn, and the inductance Ln of the components provided in the circuit block CBL are different in accordance with the resistance value Rn and the angular frequency ωn output by the low-frequency band extractor 104.

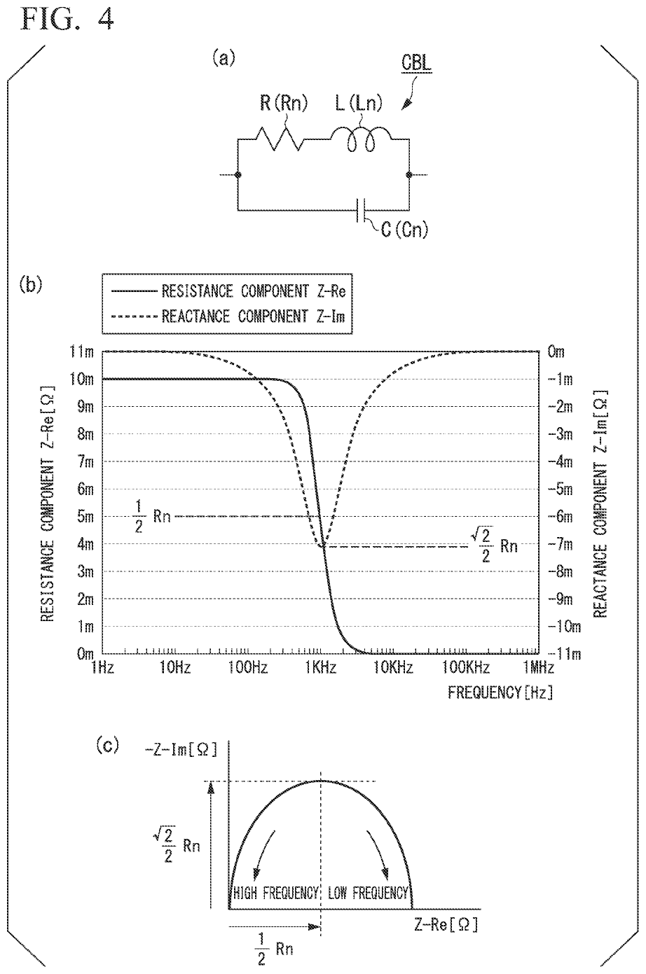

Here, the frequency characteristics of the circuit block CBL shown in (b) of FIG. 3 will be described. FIG. 4 is a diagram showing the frequency characteristics of an equivalent circuit (the circuit block CBL) in a low-frequency band configured by the equivalent circuit configurator 108 of the embodiment. A circuit configuration of one circuit block CBL is shown in (a) of FIG. 4, frequency characteristics of the impedance of one circuit block CBL are shown in (b) of FIG. 4, and a Nyquist plot (also referred to as a Cole-Cole plot) of one circuit block CBL is shown in (c) of FIG. 4.

An example shown in FIG. 4 is an example in which the circuit block CBL shown in (a) of FIG. 4 corresponds to a measurement point having a frequency of 1 [kHz] and the resistance value Rn of the resistor R constituting the circuit block CBL is, for example, Rn=10 [mΩ]. In this case, from the above Eqs. (2) and (3), the capacitance Cn of the capacitor C is Cn=22.5 [mF] and the inductance Ln of the inductor L is Ln=1.13 [μH].

Also, when the frequency characteristics of the impedance of the circuit block CBL are divided into a resistance component Z-Re (a real part) and a reactance component Z-Im (an imaginary part), characteristics as shown in (b) of FIG. 4 are obtained. More specifically, at a frequency of 1 [kHz], the resistance component Z-Re becomes 1/2Rn and the reactance component Z-Im becomes a negative extreme value at (√2/2)Rn. Also, when the frequency characteristics shown in (b) of FIG. 4 are expressed by the Nyquist plot, it is characterized that a half-circle arc trajectory in which the resistance component Z-Re is high on the low-frequency side, the resistance component Z-Re is low on the high-frequency side, the resistance component Z-Re is 1/2Rn at the center frequency (=1 [kHz]), and the reactance component Z-Im is (√2/2)Rn on the negative side is drawn as shown in (c) of FIG. 4.

The impedance Z_{BLK-L} of the circuit block CBL shown in (a) of FIG. 4 can be expressed as in the following Eq. (4).

$$\begin{matrix}{Z}_{B L K - L} = \frac{1}{\frac{1}{R n + j ω Ln} + j ω Cn} \\ = \frac{R n + j ω ( Ln - {ω}^{2} L {n}^{2} C n - C n R {n}^{2} )}{{( 1 - {ω}^{2} L n C n )}^{2} + {( ω CnRn )}^{2}}\end{matrix} \qquad ( 4 )$$

At this time, a resistance component Z_{BLK-L} (re) of the circuit block CBL can be expressed as in the following Eq. (5).

$${Z}_{B L K - L} ( r e ) = \frac{R n}{{( 1 - {ω}^{2} L n C n )}^{2} + {( ω CnRn )}^{2}} \qquad ( 5 )$$

Here, when the capacitance Cn is replaced with Cn=k/(Rnω₀) and the inductance Ln is replaced with Ln=Rn/(kω₀), the resistance component Z_{BLK-L} (re) represented by the above Eq. (5) can be expressed as in the following Eq. (6). Here, k is a constant.

$$\begin{matrix}{Z}_{B L K - L} ( r e ) = \frac{R n}{{( 1 - {ω}^{2} \frac{R n}{k {ω}_{0}} \frac{k}{Rn {ω}_{0}} )}^{2} + {( ω \frac{k}{Rn {ω}_{0}} R n )}^{2}} \\ = \frac{R n}{( 1 - \frac{{ω}^{2}}{{ω}_{0}^{2}} ) + {( \frac{ω}{{ω}_{0}} k )}^{2}} \\ = \frac{R n}{1 + ( {k}^{2} - 2 ) \frac{{ω}^{2}}{{ω}_{0}^{2}} + \frac{{ω}^{4}}{{ω}_{0}^{4}}}\end{matrix} \qquad ( 6 )$$

From the above Eq. (6), a slope (Z_{BLK-L}(re))′ of the resistance component of the circuit block CBL can be expressed as in the following Eq. (7).

$$\begin{matrix}{( {Z}_{BLK - L} ( r e ) )}^{′} = {Rn ( \frac{1}{1 + ( {k}^{2} - 2 ) \frac{{ω}^{2}}{{ω}_{0}^{2}} + \frac{{ω}^{4}}{{ω}_{0}^{4}}} )}^{′} \\ = R {n ( 1 + ( {k}^{2} - 2 ) \frac{{ω}^{2}}{{ω}_{0}^{2}} + \frac{{ω}^{4}}{{ω}_{0}^{4}} )}^{- 2} ( 2 ( {k}^{2} - 2 ) \frac{ω}{{ω}_{0}^{2}} + 4 \frac{{ω}^{3}}{{ω}_{0}^{4}} )\end{matrix} \qquad ( 7 )$$

From the above Eq. (7), if the constant k is k≥√2, the slope (Z_{BLK-L}(re))′ of the resistance component is (Z_{BLK-L}(re))′≤0 and is in a negative state all the time.

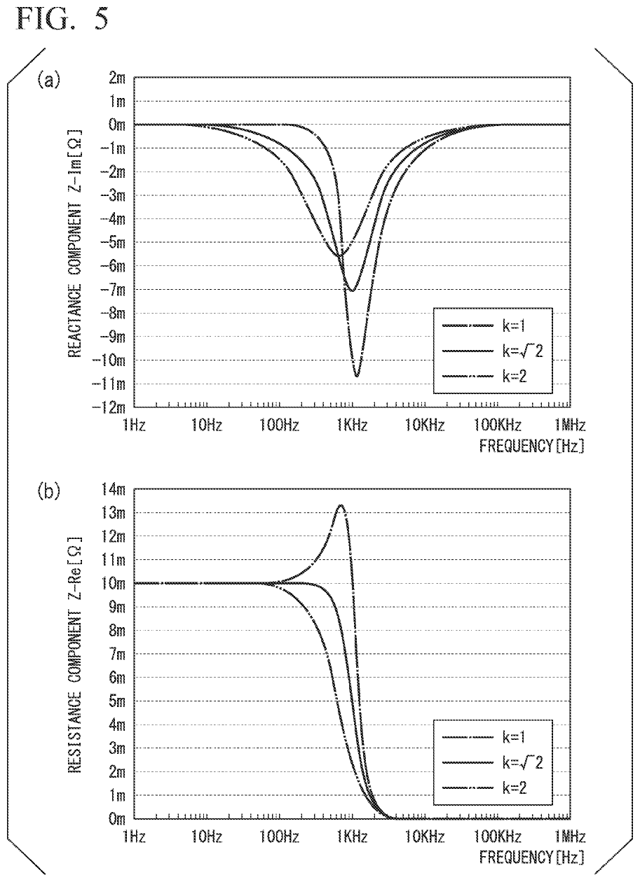

Here, for a comparison, the difference between the frequency characteristics of the impedance of the circuit block CBL when the constant k is changed will be described. FIG. 5 is a diagram showing the difference between frequency characteristics when the constant k is changed in the equivalent circuit (the circuit block CBL) in the low-frequency band of the embodiment. The reactance component Z-Im when the constant k is different in the circuit block CBL is shown in (a) of FIG. 5 and the resistance component Z-Re when the constant k is different in the circuit block CBL is shown in (b) of FIG. 5. In FIG. 5, the reactance component Z-Im and the resistance component Z-Re when the constant k is k=1, k=√2, and k=2 are shown. As shown in (a) of FIG. 5, when the constant k is k=√2, the reactance component Z-Im has a negative extreme value at the center frequency (=1 [kHz]). On the other hand, when the constant k is k<√2 (here, when the constant k is k=1), the change in the reactance component Z-Im increases, but the extreme value moves from the center frequency to the high-frequency side. When the constant k is k>√2 (here, when the constant k is k=2), the change in the reactance component Z-Im decreases and the extreme value moves from the center frequency to the low-frequency side. On the other hand, as shown in (b) of FIG. 5, when the constant k is k=√2, the flat portion of the resistance component Z-Re on the low-frequency side is longest and the change from the high-resistance side to the low-resistance side is also relatively steep. On the other hand, when the constant k is k<V2 (here, when the constant k is k=1), the change from the high-resistance side to the low-resistance side in a change of the resistance component Z-Re is steeper than when k=√2 but the peak at which the resistance value increases in the vicinity of the center frequency appears. When the constant k is k>√2 (here, when the constant k is k=2), the peak of the resistance component Z-Re does not appear in the vicinity of the center frequency, but the change from the high-resistance side to the low-resistance side in the change of the resistance component Z-Re becomes gradual, and the flat portion on the low-frequency side becomes short. From these, k=√2 is considered to be preferable as the constant k when the capacitance Cn and the inductance Ln are calculated in the circuit block CBL.

Returning to FIG. 3, the high-frequency band extractor 106 extracts a resistance value Rⱼ at each measurement point (angular frequency ωj) located in a higher-frequency band than the minimum measurement point on the basis of the characteristics of the resistance component Z-Re shown in (a) of FIG. 3. The high-frequency band extractor 106 extracts, for example, a resistance value Rⱼ at an angular frequency ωj+1 and a resistance value Rⱼ₊₁ at an angular frequency ωj+1 that is a measurement point adjacent to a side having a higher frequency than the angular frequency ωj. The high-frequency band extractor 106 calculates the resistance value Rm which is the difference between the extracted resistance values of the two adjacent measurement points according to the following Eq. (8).

Rm=Rⱼ₊₁−RR (8)

In (a) of FIG. 3, an example in which the high-frequency band extractor 106 calculates the difference between a resistance value Rⱼ₊₂ at an angular frequency ωj+2 and a resistance value Rⱼ₊₃ at an angular frequency ωj+3 as the resistance value Rm is shown. Further, in (a) of FIG. 3, an example in which the high-frequency band extractor 106 sets a central angular frequency ω between the angular frequency ωj+2 and the angular frequency ωj+3 as an angular frequency ωm corresponding to the calculated resistance value Rm is shown.

The equivalent circuit configurator 108 calculates the capacitance Cm according to the following Eq. (9) on the basis of the resistance value Rm and the angular frequency ωm output by the high-frequency band extractor 106, and calculates the inductance Lm according to the following Eq. (10).

Cm=√2/(Rmωm) (9)

Lm=Rm/((√2)ωm) (10)

As shown in (c) of FIG. 3, the equivalent circuit configurator 108 configures the circuit block CBH in which a resistor R with the resistance value Rm and a capacitor C with capacitance Cm are connected in series and an inductor L of inductance Lm is connected in parallel to this series circuit as an equivalent circuit corresponding to the resistance value Rm and the angular frequency ωm output by the high-frequency band extractor 106. That is, the equivalent circuit configurator 108 configures an equivalent reproduction circuit including the circuit block CBH shown in (c) of FIG. 3 as an equivalent circuit for reproducing battery characteristics in a higher-frequency band than the minimum measurement point. The equivalent circuit configurator 108 provides the circuit block CBH shown in (c) of FIG. 3 for each measurement point located in a higher-frequency band than the minimum measurement point. However, values of the resistance value Rm, the capacitance Cm, and the inductance Lm of constituent elements provided in the circuit block CBH are different in accordance with the resistance value Rm and the angular frequency ωm output by the high-frequency band extractor 106.

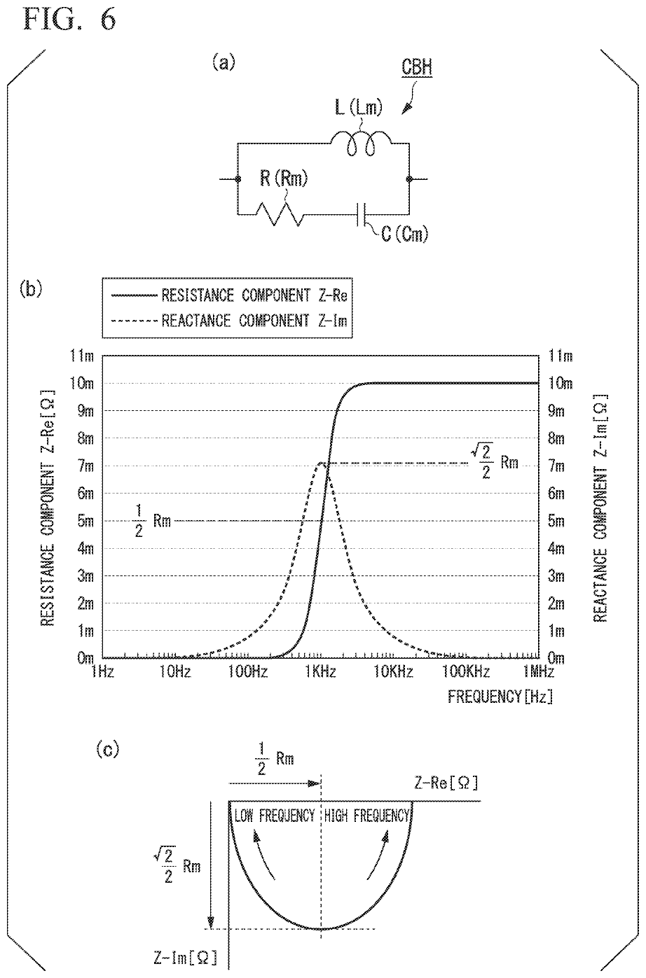

Here, the frequency characteristics of the circuit block CBH shown in (c) of FIG. 3 will be described. FIG. 6 is a diagram showing frequency characteristics of an equivalent circuit (the circuit block CBH) in the high-frequency band configured by the equivalent circuit configurator 108 of the embodiment. In (a) of FIG. 6, the circuit configuration of one circuit block CBH is shown. In (b) of FIG. 6, the frequency characteristics of the impedance of one circuit block CBH is shown. In (c) of FIG. 6, a Nyquist plot of one circuit block CBH is shown.

An example shown in FIG. 6 is an example in which the circuit block CBH shown in (a) of FIG. 6 also corresponds to a measurement point having a frequency of 1 [kHz] and the resistance value Rm of the resistor R constituting the circuit block CBH is, for example, Rm=10 [mΩ].In this case, from the above Eqs. (9) and (10), the capacitance Cm of the capacitor C is Cm=22.5 [mF] and the inductance Lm of the inductor L is Lm=1.13 [μH].

Also, when the frequency characteristics of the impedance of the circuit block CBH are divided into a resistance component Z-Re (a real part) and a reactance component Z-Im (an imaginary part), the characteristics as shown in (b) of FIG. 6 are obtained. More specifically, at a frequency of 1 [kHz], it is characterized that the resistance component Z-Re becomes 1/2Rm and the reactance component Z-Im becomes a positive extreme value at (√2/2)Rm. Also, when the frequency characteristics shown in (b) of FIG. 6 are expressed by the Nyquist plot, it is characterized that a half-circle arc trajectory in which the resistance component Z-Re is low on the low-frequency side, the resistance component Z-Re is high on the high-frequency side, the resistance component Z-Re is 1/2Rm at the center frequency (=1 [kHz]), and the reactance component Z-Im is (√2/2)Rm on the positive side is drawn as shown in (c) of FIG. 6. That is, the characteristics of the resistance component Z-Re and the reactance component Z-Im in the circuit block CBH are opposite to the characteristics in the circuit block CBL. The impedance Z_{BLK-H} of the circuit block CBH shown in (a) of FIG. 6 can be expressed as in the following Eq. (11).

$$\begin{matrix}{Z}_{BLK - H} = \frac{1}{\frac{1}{R m + \frac{1}{j ω Cm}} + \frac{1}{j ω Lm}} \\ = \frac{{ω}^{4} R m C {m}^{2} L {m}^{2} - j ω Lm ( - 1 + {ω}^{2} L mCm - {ω}^{2} C {m}^{2} R {m}^{2} )}{{( 1 - {ω}^{2} L m C m )}^{2} + {( ω CmRm )}^{2}}\end{matrix} \qquad ( 11 )$$

At this time, the resistance component Z_{BLK-H}(re) of the circuit block CBH can be expressed as in the following Eq. (12).

$${Z}_{B L K - H} = \frac{{ω}^{4} R m C {m}^{2} L {m}^{2}}{{( 1 - {ω}^{2} L m C m )}^{2} + {( ω C m R m )}^{2}} \qquad ( 12 )$$

Here, when the capacitance Cm is replaced with Cm=k/(Rmω₀) and the inductance Lm is replaced with Lm=Rm/(kω₀), the resistance component Z_{BLK-H}(re) represented by the above Eq. (12) can be expressed as in the following Eq. (13). In this case, k is also a constant.

$$\begin{matrix}{Z}_{B L K - H} ( r e ) = \frac{{ω}^{4} R {m ( \frac{k}{R m {ω}_{0}} )}^{2} {( \frac{R m}{k {ω}_{0}} )}^{2}}{{( 1 - {ω}^{2} \frac{R m}{k {ω}_{0}} \frac{k}{Rm {ω}_{0}} )}^{2} + {( ω \frac{k}{Rm {ω}_{0}} R m )}^{2}} \\ = \frac{{ω}^{4} \frac{R}{{ω}_{0}^{4}}}{{( 1 - \frac{{ω}^{2}}{{ω}_{0}^{2}} )}^{2} + {( \frac{ω k}{{ω}_{0}} )}^{2}} \\ = \frac{\frac{R}{{ω}_{0}^{4}}}{\frac{1}{{ω}^{4}} + ( {k}^{2} - 2 ) \frac{1}{{ω}^{2} {ω}_{0}^{2}} + \frac{1}{{ω}_{0}^{4}}}\end{matrix} \qquad ( 13 )$$

From the above Eq. (13), the slope (Z_{BLK-H}(re))′ of the resistance component of the circuit block CBH can be expressed as in the following Eq. (14).

$$\begin{matrix}{( {Z}_{B L K - H} ( re ) )}^{′} = \frac{R m}{{ω}_{0}^{4}} {( \frac{1}{\frac{1}{{ω}^{4}} + ( {k}^{2} - 2 ) \frac{1}{{ω}^{2} {ω}_{0}^{2}} + \frac{1}{{ω}_{0}^{4}}} )}^{′} \\ = \frac{R m}{{ω}_{0}^{4}} {( \frac{1}{{ω}^{4}} + ( {k}^{2} - 2 ) \frac{1}{{ω}^{2} {ω}_{0}^{2}} + \frac{1}{{ω}_{0}^{4}} )}^{- 2} ( 4 \frac{1}{{ω}^{5}} + 2 ( {k}^{2} - 2 ) \frac{1}{{ω}^{3} {ω}_{0}^{2}} )\end{matrix} \qquad ( 14 )$$

From the above Eq. (14), if the constant k is k≥√2, the slope (Z_{BLK-H}(re))′ of the resistance component is (Z_{BLK-H}(re))′≥0, and is in a positive state all the time.

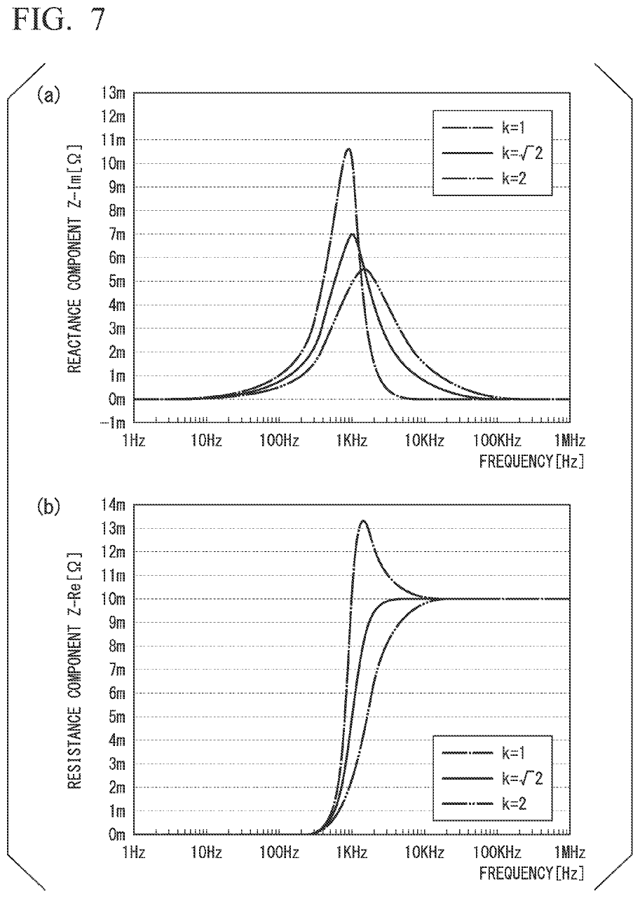

Here, for a comparison, the difference between the frequency characteristics of the impedance of the circuit block CBH when the constant k is changed will be described. FIG. 7 is a diagram showing a difference between frequency characteristics when the constant k is changed in the equivalent circuit (the circuit block CBH) in the high-frequency band of the embodiment. In (a) of FIG. 7, the reactance component Z-Im when the constant k is different in the circuit block CBH is shown. In (b) of FIG. 7, the resistance component Z-Re when the constant k is different in the circuit block CBH is shown. In FIG. 7, the reactance component Z-Im and the resistance component Z-Re when the constant k is k=1, k=√2, and k=2 are shown. As shown in (a) of FIG. 7, when the constant k is k=√2, the reactance component Z-Im has a positive extreme value at the center frequency (=1 [kHz]). On the other hand, when the constant k is k<√2 (here, when the constant k is k=1), the change in the reactance component Z-Im increases, but the extreme value moves from the center frequency to the low-frequency side. When the constant k is k>√2 (here, when the constant k is k=2), the change in the reactance component Z-Im becomes small, and the extreme value moves from the center frequency to the high-frequency side. On the other hand, as shown in (b) of FIG. 7, when the constant k is k=√2, the flat portion of the resistance component Z-Re on the high-frequency side becomes longest, and the change from the low-resistance side to the high-resistance side is also relatively steep. On the other hand, when the constant k is k<√2 (here, when the constant k is k=1), the change from the low-resistance side to the high-resistance side in the change of the resistance component Z-Re is steeper than when k=√2 but the peak at which the resistance value becomes large in the vicinity of the center frequency appears. When the constant k is k>√2 (here, when the constant k is k=2), the peak of the resistance component Z-Re does not appear in the vicinity of the center frequency, but the change from the low-resistance side to the high-resistance side in the change of the resistance component Z-Re becomes gradual and the flat portion on the high-frequency side becomes short. From these, it is considered that k=√2 is preferable for the constant k when the capacitance Cn and the inductance Ln are also calculated in the circuit block CBH like the circuit block CBL.

The equivalent circuit configurator 108 configures any one of the resistor R0 based on the resistance value Rs output by the smallest value extractor 102, the circuit block CBL based on the resistance value Rn and the angular frequency ωn output by the low-frequency band extractor 104, and the circuit block CBH based on the resistance value Rm and the angular frequency ωm output by the high-frequency band extractor 106 for each measurement point. Also, the equivalent circuit configurator 108 configures an equivalent reproduction circuit for reproducing impedance characteristics of the battery representing input battery characteristic data by connecting the resistor R0, the circuit block CBL, and the circuit block CBH configured for each measurement point in series.

### First Embodiment

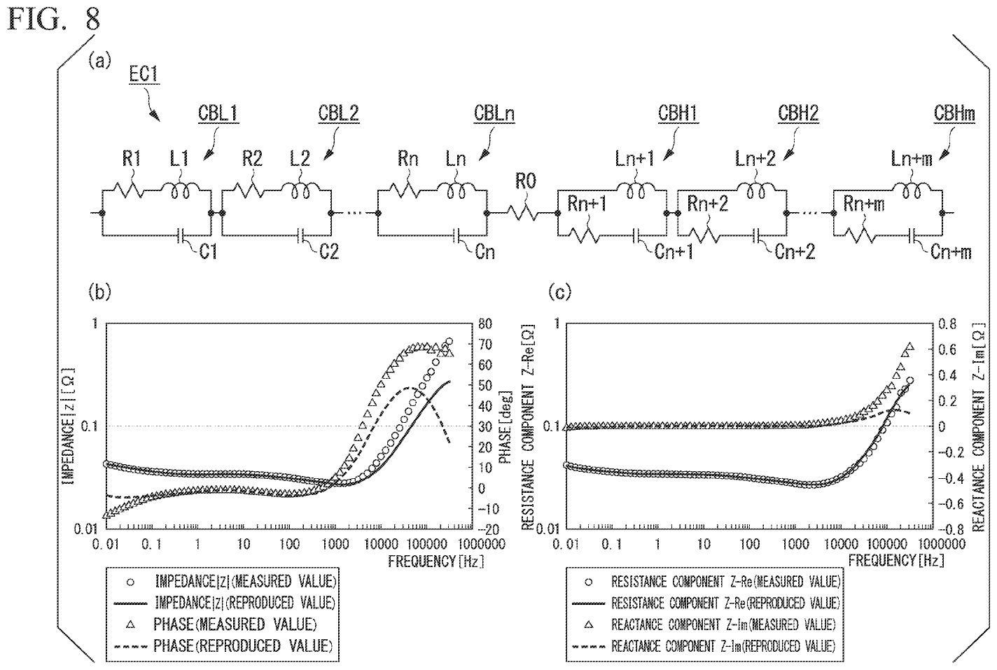

Next, an equivalent reproduction circuit configured in the battery characteristic reproduction device 100 will be described as a first embodiment. FIG. 8 is a diagram showing an example of a configuration of an equivalent reproduction circuit (the equivalent reproduction circuit of the first embodiment) configured by the battery characteristic reproduction device 100 of the embodiment and its characteristics. In (a) of FIG. 8, an example of an equivalent reproduction circuit (hereinafter referred to as an “equivalent reproduction circuit EC1”) configured by the battery characteristic reproduction device 100 (more specifically, the equivalent circuit configurator 108) is shown. (b) of FIG. 8 shows the impedance |z| (absolute value) included in the impedance characteristics and the phase in a Bode plot. (c) of FIG. 8 illustrates frequency characteristics shown by dividing data identical to impedance |z| shown in (b) of FIG. 8 into a resistance component Z-Re (a real part) and a reactance component Z-Im (an imaginary part). In (b) of FIG. 8 and (c) of FIG. 8, for a comparison, a measured value represented by the measured impedance characteristic (the impedance characteristic input to the battery characteristic reproduction device 100) and a reproduced value (a calculated value) of the impedance characteristic calculated (simulated) using the equivalent reproduction circuit EC1 are also shown. The characteristics of the measured values of the impedance |z| and the phase in (b) of FIG. 8 and the measured values of the resistance component Z-Re and the reactance component Z-Im in (c) of FIG. 8 are the same as the characteristics shown in FIG. 2.

In the equivalent reproduction circuit EC1 shown in (a) of FIG. 8, a circuit block CBL1 including a resistor R1, an inductor L1, and a capacitor C1, a circuit block CBL2 including a resistor R2, an inductor L2, and a capacitor C2, a circuit block CBLn including a resistor Rn, an inductor Ln, and a capacitor Cn, a circuit block CBH1 including a resistor R0, a resistor Rn+1, an inductor Ln+1, and a capacitor Cn+1, a circuit block CBH2 including a resistor Rn+2, an inductor Ln+2, and a capacitor Cn+2, and a circuit block CBHm including a resistor Rn+m, an inductor Ln+m, and a capacitor Cn+m are connected in series in that order. Because the equivalent reproduction circuit EC1 has a configuration in which the resistor R0, a plurality of circuit blocks CBL, and a plurality of circuit blocks CBH are connected in series, the order in which constituent elements are connected does not affect the impedance characteristics of the battery to be reproduced.

When the impedance characteristics calculated using the equivalent reproduction circuit EC1 are compared with the Bode plot shown in (b) of FIG. 8, it can be seen that the measured value and the reproduced value generally match at a frequency of 4 [kHz] or lower at which the characteristic of the resistance component Z-Re is a minimum point (a point where the resistance value is smallest) in the impedance |z|. Furthermore, it can be seen that the phase generally matches the measured value and the reproduced value in a frequency range of 0.1 [Hz] to 1 [kHz]. On the other hand, when the impedance characteristics calculated using the equivalent reproduction circuit EC1 are compared with the frequency characteristics shown in (c) of FIG. 8, the resistance component Z-Re generally matches a measured value and a reproduced value at all frequencies and the reactance component Z-Im generally matches a measured value and a reproduced value at a frequency of 10 [kHz] or lower.

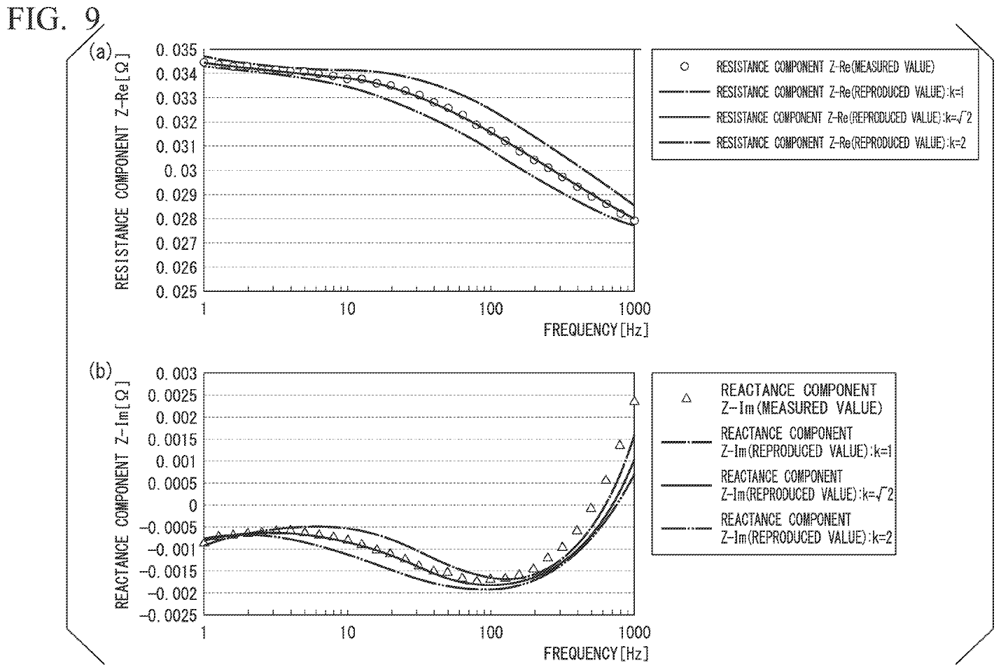

Here, the matching degree between the measured value and the reproduced value in the resistance component Z-Re and the reactance component Z-Im will be described. FIG. 9 is a diagram showing the matching degree of impedance characteristics of the equivalent reproduction circuit (the equivalent reproduction circuit EC1) configured by the battery characteristic reproduction device 100 of the embodiment. In (a) of FIG. 9, the frequency characteristics of the resistance component Z-Re are shown. In (b) of FIG. 9, the frequency characteristics of the reactance component Z-Im are shown. In (a) of FIG. 9 and (b) of FIG. 9, the difference between frequency characteristics in the equivalent reproduction circuit configured by temporarily changing the constant k in the circuit block CBL and the circuit block CBH constituting the equivalent reproduction circuit EC1 is shown. More specifically, the difference between frequency characteristics in each equivalent reproduction circuit is shown by temporarily changing the constant k of each of the capacitance Cn (Cn=k/(Rnω₀)) and the inductance Ln (Ln=Rn/(kω₀)) in the circuit block CBL and the capacitance Cm (Cm=k/(Rmω₀)) and the inductance Lm (Lm=Rm/(kω₀)) in the circuit block CBH to k=1, k=√2, or k=2.

When the comparison with the resistance component Z-Re shown in (a) of FIG. 9 is made, it can be seen that the frequency characteristics of the reproduced value of the resistance component Z-Re generally match the frequency characteristics of the measured value of the resistance component Z-Re if the constant k is k=√2. On the other hand, when the constant k is k=1, it can be seen that the frequency characteristics of the reproduced value of the resistance component Z-Re generally have a larger value than the frequency characteristics of the measured value of the resistance component Z-Re. When the constant k is k=2, it can be seen that the frequency characteristics of the reproduced value of the resistance component Z-Re generally have a smaller value than the frequency characteristics of the measured value of the resistance component Z-Re. On the other hand, when the comparison with the reactance component Z-Im shown in (b) of FIG. 9 is made, it can be seen that the measured value of the component Z-Im generally matches the measured value of the reactance component Z-Im at a frequency of 100 [Hz] or lower, but is gradually smaller than the measured value of the reactance component Z-Im at a frequency higher than 100 [Hz] if the constant k is k=√2. On the other hand, when the constant k is k=1, it can be seen that the reproduced value of the reactance component Z-Im has a tendency similar to that when the constant k is k=√2 at a frequency higher than 100 [Hz], but there is also a difference from the measured value of the reactance component Z-Im (there is generally the difference from a larger value) at a frequency of 100 [Hz] or lower. When the constant k is k=2, it can be seen that the reproduced value of the reactance component Z-Im has a tendency similar to that when the constant k is k=√2 at a frequency higher than 100 [Hz], but there is also the difference from the measured value of the reactance component Z-Im (there is generally the difference from a smaller value) at a frequency of 100 [Hz] or lower. From these, it can be confirmed that k=√2 is preferable for the constant k in the circuit block CBL and the circuit block CBH.

Thus, the battery characteristic reproduction device 100 can reproduce (calculate) impedance characteristics similar to impedance characteristics obtained by actually measuring a target battery constituting the equivalent reproduction circuit EC1 in the prescribed frequency range as described above by configuring the equivalent reproduction circuit EC1 as shown in (a) of FIG. 8 on the basis of the impedance characteristics of the battery represented by the input battery characteristic data. Moreover, in the battery characteristic reproduction device 100, it is possible to configure the equivalent reproduction circuit EC1 only by performing a simple process in which the smallest value extractor 102 extracts the resistance value Rs, the low-frequency band extractor 104 extracts the resistance value Rn and the angular frequency ωn, the high-frequency band extractor 106 extracts the resistance value Rm and the angular frequency ωm, and the equivalent circuit configurator 108 applies each extracted value to a prescribed circuit configuration. Thereby, various states inside of the battery can be estimated by calculating the response, behavior, and the like when a current is applied to the battery using the equivalent reproduction circuit EC1 configured by the battery characteristic reproduction device 100.

### Second Embodiment

Next, in impedance characteristics calculated using the equivalent reproduction circuit EC1 of the first embodiment configured by the battery characteristic reproduction device 100, an example of a method of configuring an equivalent reproduction circuit for focusing on the difference in the reactance component Z-Im generated on the high-frequency side (see (c) of FIG. 8) and further reducing this difference will be described as a second embodiment.

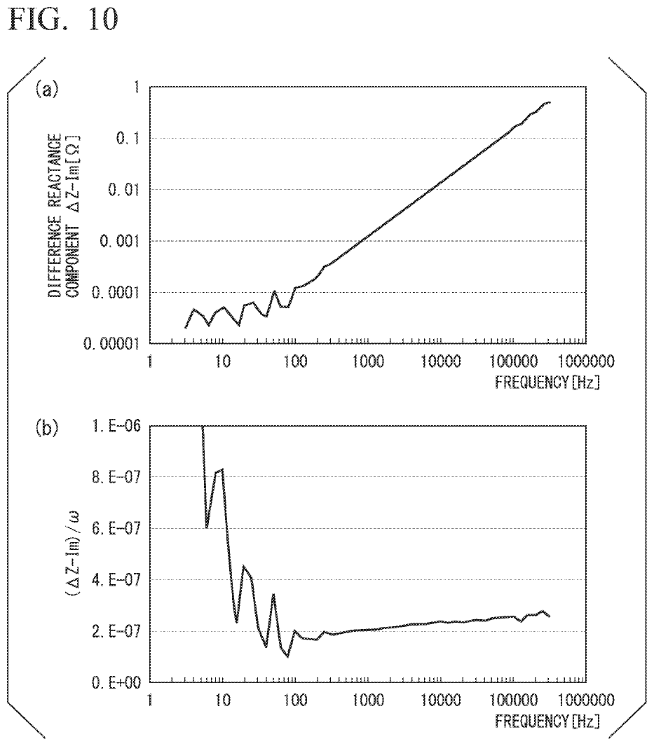

FIG. 10 is a diagram showing an example of the characteristics of the reactance component in the equivalent reproduction circuit (the equivalent reproduction circuit EC1) configured by the battery characteristic reproduction device 100 of the embodiment. In (a) of FIG. 10, the frequency characteristics of the difference between the measured value of the reactance component Z-Im and the reproduced value (hereinafter referred to as a “difference reactance component ΔZ-Im”) is shown. In (b) of FIG. 10, the frequency characteristics when the difference reactance component ΔZ-Im is divided by the angular frequency to (=(ΔZ-Im)/w) are shown.

As shown in (a) of FIG. 10, the frequency characteristics of the difference reactance component ΔZ-Im are generally linear at a frequency of 100 [Hz] or higher. In other words, the frequency characteristics of the difference reactance component ΔZ-Im are linear characteristics at a frequency of 10 [kHz] or higher where the difference between the measured value and the reproduced value occurs in the reactance component Z-Im. As shown in (b) of FIG. 10, the frequency characteristics of (ΔZ-Im)/ω have a nearly flat value at a frequency in a range of 100 [Hz] to 100 [kHz]. Here, because the unit of the difference reactance component ΔZ-Im is Ohm ([Ω]), a value (=(ΔZ-Im)ω) obtained by dividing the difference reactance component ΔZ-Im by the angular frequency to corresponds to Henry ([H]). That is, the value obtained by dividing the difference reactance component ΔZ-Im by the angular frequency to corresponds to the inductance (hereinafter referred to as “inductance Ls”).

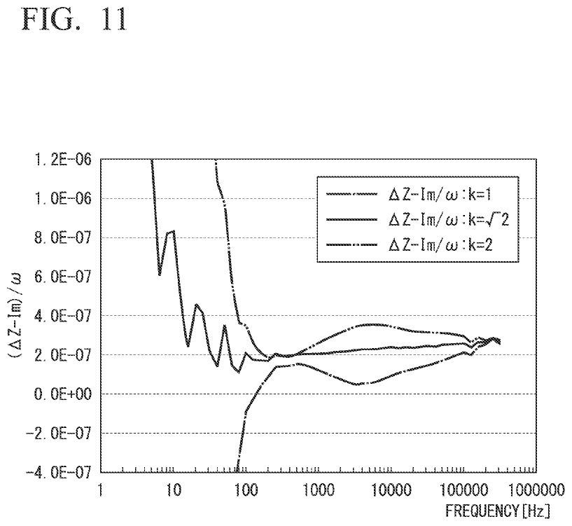

Here, the difference (hereinafter referred to as “inductance Ls”) between frequency characteristics of the value obtained by dividing the difference reactance component ΔZ-Im by the angular frequency to will be described. FIG. 11 is a diagram showing an example of the frequency characteristics of the reactance component (inductance Ls) in an equivalent reproduction circuit configured by the battery characteristic reproduction device 100 of the embodiment. In FIG. 11, the difference between frequency characteristics of the inductance Ls is shown when the constant k of each of capacitance Cn (Cn=k/(Rnω₀)) and inductance Ln (Ln=Rn/(kω₀)) in the circuit block CBL constituting the equivalent reproduction circuit and the capacitance Cm (Cm=k/(Rmω₀)) and the inductance Lm (Lm=Rm/(kω₀)) in the circuit block CBH is temporarily changed to k=1, k=√2, or k=2.

As shown in FIG. 11, when the constant k is k=√2, the frequency characteristic of the inductance Ls has a nearly flat value at a frequency in the range of 100 [Hz] to 100 [kHz] as described above. On the other hand, when the constant k is k=1 or the constant k is k=2, it can be seen that the inductance Ls fluctuates with the frequency and the frequency characteristic has a value that cannot be said to be nearly flat. From these, it can be confirmed that k=√2 is preferable for the constant k in the circuit block CBL and the circuit block CBH.

Therefore, the equivalent circuit configurator 108 configures an equivalent reproduction circuit for reducing (correcting) the difference in the reactance component Z-Im generated on the high-frequency side by connecting (inserting) the inductor L0 having inductance Ls that is nearly flat in (b) of FIG. 10 or FIG. 11 in series with the equivalent reproduction circuit EC1 shown in (a) of FIG. 8. The inductance Ls of the inductor L0 inserted here may be determined, for example, by the high-frequency band extractor 106 extracting the reactance component Z-Im on the high-frequency side on the basis of the input battery characteristic data. For example, the inductance Ls of the inductor L0 may be determined by calculating the difference between the reactance component Z-Im (reproduced value) calculated using the equivalent reproduction circuit EC1 and the reactance component Z-Im (measured value) indicated in the input battery characteristic data after the equivalent circuit configurator 108 temporarily configures the equivalent reproduction circuit EC1 as shown in (a) of FIG. 8. At this time, the equivalent circuit configurator 108 may average values of a nearly flat portion to decide on the inductance Ls of the inductor L0.

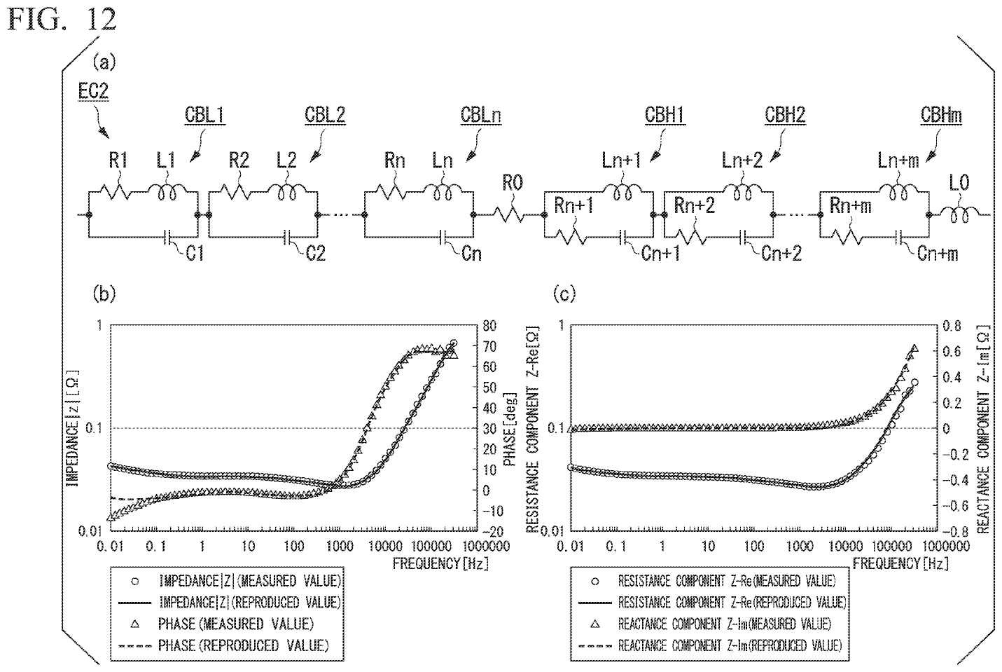

FIG. 12 is a diagram showing an example of a configuration of an equivalent reproduction circuit (an equivalent reproduction circuit of the second embodiment) configured by the battery characteristic reproduction device 100 of the embodiment and its characteristics. In (a) of FIG. 12, an example of an equivalent reproduction circuit (hereinafter referred to as an “equivalent reproduction circuit EC2”) configured by the battery characteristic reproduction device 100 (more specifically, the equivalent circuit configurator 108) is shown. (b) of FIG. 12 shows the impedance |z| (absolute value) included in the impedance characteristic and the phase in a Bode plot. (c) of FIG. 12 illustrates frequency characteristics shown by dividing data identical to impedance |z| shown in (b) of FIG. 12 into a resistance component Z-Re (a real part) and a reactance component Z-Im (an imaginary part). As in (b) of FIG. 8 and (c) of FIG. 8, the measured value and the reproduced value (calculated value) of the impedance characteristic are also shown for a comparison in (b) of FIG. 12 and (c) of FIG. 12. The characteristics of the measured values in (b) of FIG. 12 and (c) of FIG. 12 are the same as the characteristics shown in FIG. 2 as in (b) of FIG. 8 and (c) of FIG. 8.

In the equivalent reproduction circuit EC2 shown in (a) of FIG. 12, the inductor L0 is connected in series with a stage subsequent to the circuit block CBHm in the equivalent reproduction circuit EC1 of the first embodiment shown in (a) of FIG. 8. Also, in the equivalent reproduction circuit EC2, because the resistor R0, a plurality of circuit blocks CBL, a plurality of circuit blocks CBH, and the inductor L0 are connected in series, the order in which constituent elements are connected does not affect the impedance characteristics of the battery to be reproduced.

When the impedance characteristics calculated using the equivalent reproduction circuit EC2 are compared with the Bode plot shown in (b) of FIG. 12, it can be seen that the impedance |z| generally matches the measured value and the reproduced value at all frequencies and the phase generally matches the measured value and the reproduced value at a frequency of 0.1 [Hz] or higher. On the other hand, when the impedance characteristics calculated using the equivalent reproduction circuit EC2 are compared with the frequency characteristics shown in (c) of FIG. 12, it can be seen that a measured value and a reproduced value generally match at all frequencies in both the resistance component Z-Re and the reactance component Z-Im.

Thus, the battery characteristic reproduction device 100 can reproduce (calculate) impedance characteristics similar to impedance characteristics obtained by actually measuring the target battery constituting the equivalent reproduction circuit EC2 in the range of almost all frequencies as described above by configuring the equivalent reproduction circuit EC2 as shown in (a) of FIG. 12 on the basis of the difference between the measured value and the reproduced value (calculated value) of the reactance component Z-Im generated on the high-frequency side. Moreover, in the battery characteristic reproduction device 100, it is possible to configure the equivalent reproduction circuit EC2 only by performing a simple process of making a series connection (insertion) of the inductor LO of the inductance Ls based on the difference between the measured value and the reproduced value (calculated value) of the reactance component Z-Im. Thereby, various states inside of the battery can be estimated with higher accuracy by calculating the response, behavior, and the like when a current is applied to the battery using the equivalent reproduction circuit EC2 configured by the battery characteristic reproduction device 100.

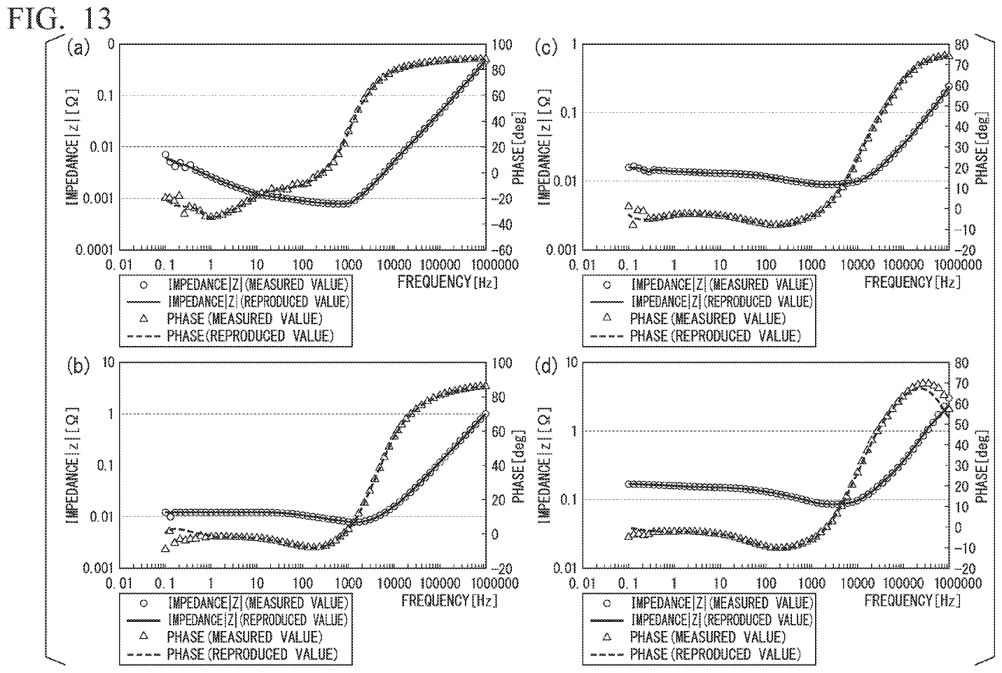

Here, an example in which the battery characteristic reproduction device 100 configures an equivalent reproduction circuit EC2 when battery characteristic data of batteries having different configurations is input will be described. FIG. 13 is a diagram showing an example of the impedance characteristics of an equivalent reproduction circuit (equivalent reproduction circuit EC2) configured by the battery characteristic reproduction device 100 of the embodiment. As an example shown in FIG. 13, the impedance |z| (absolute value) included in the impedance characteristics when the battery characteristic reproduction device 100 configures the equivalent reproduction circuit EC2 corresponding to four types of batteries having different configurations and the phase are shown in a Bode plot. The impedance characteristics shown in (a) of FIG. 13 are represented by, for example, a Bode plot of a rectangular battery. The impedance characteristics shown in (b) of FIG. 13 are represented by, for example, a Bode plot of a battery having a configuration in which a plurality of rectangular batteries are connected and used as a module (an assembled battery). The impedance characteristics shown in (c) of FIG. 13 are represented by, for example, a Bode plot of a battery for a specific application. The impedance characteristics shown in (d) of FIG. 13 are represented by, for example, a Bode plot of a battery having a configuration in which a plurality of batteries for a specific application are connected and used as a module.

As can be seen from each of the Bode plots shown in (a) to (d) of FIG. 13, in the equivalent reproduction circuit EC2 configured by the battery characteristic reproduction device 100, regardless of the battery configuration, it can be seen that the measured value and the reproduced value at the impedance |z| (absolute value) and the phase generally match at a frequency of 1 [Hz] or higher. That is, it can be seen that the battery characteristic reproduction device 100 can accurately reproduce the impedance characteristics represented by the input battery characteristic data regardless of the battery configuration. Meanwhile, in the battery used as a module shown in (b) or (d) of FIG. 13, it is conceivable that the batteries are connected to each other by, for example, a battery connection part such as a bus bar. From this, it can be seen that the battery characteristic reproduction device 100 constitutes an equivalent reproduction circuit EC2 that reproduces the overall impedance characteristics including the characteristics of the battery connection part such as a bus bar.

### Third Embodiment

Next, an example of a method of focusing on the difference in the reactance component Z-Im generated on a low-frequency side and configuring the equivalent reproduction circuit for further reducing the difference in a more detailed view of the impedance characteristics calculated using the equivalent reproduction circuit EC1 of the first embodiment configured by the battery characteristic reproduction device 100 will be described as a third embodiment.

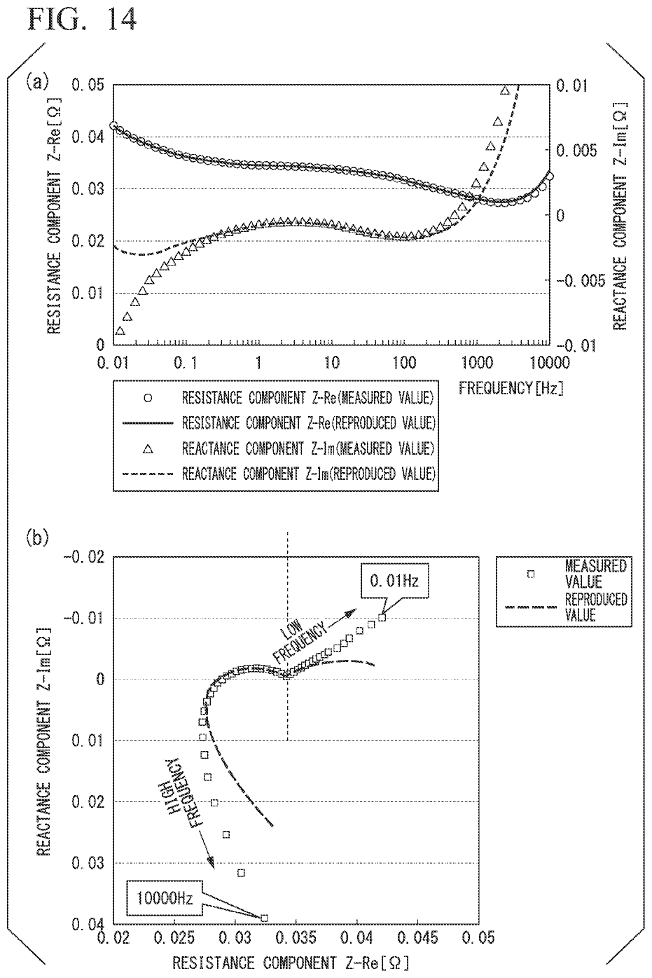

FIG. 14 is a diagram showing an example of a matching degree of the impedance characteristics of the equivalent reproduction circuit (the equivalent reproduction circuit EC1) configured by the battery characteristic reproduction device 100 of the embodiment. (a) of FIG. 14 illustrates frequency characteristics shown by dividing each of a measured value of the impedance |z| (absolute value) represented by the measured impedance characteristic and a reproduced value (a calculated value) of the impedance |z| (absolute value) represented by the impedance characteristic calculated (simulated) using the equivalent reproduction circuit EC1 into a resistance component Z-Re (a real part) and a reactance component Z-Im (an imaginary part). (a) of FIG. 14 is an enlarged version of the low-frequency side (a range up to 10 [kHz]) in the frequency characteristics shown in (c) of FIG. 8. (b) of FIG. 14 illustrates frequency characteristics shown in (a) of FIG. 14 by a Nyquist plot.

Although the resistance component Z-Re has a measured value and a reproduced value that generally match at all frequencies as can be seen from the frequency characteristics shown in (a) of FIG. 14, the reactance component Z-Im has a difference between the measured value and the reproduced value at a frequency lower than about 0.2 [Hz]. Looking at this in the Nyquist plot shown in (b) of FIG. 14, as the frequency decreases (moves to the low-frequency side) from a point where the reactance component Z-Im is 0 [Ω], the characteristic of the measured value extending linearly in the right oblique upward direction on the Nyquist plot can be confirmed. This characteristic is what is commonly known as the Warburg resistance characteristic. It can be seen that a difference occurs in this part of the Warburg resistance characteristic in the reproduced value of the Nyquist plot shown in (b) of FIG. 14. Here, in the Nyquist plot shown in (b) of FIG. 14, it is considered that the difference between the measured value and the reproduced value on the high-frequency side can be reduced by the equivalent reproduction circuit EC2 of the second embodiment described above.

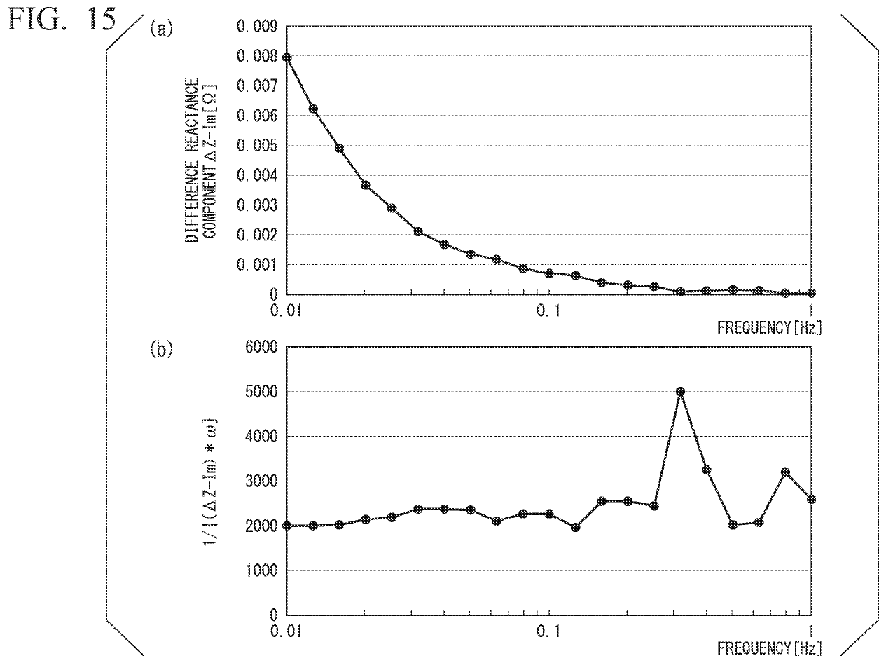

Therefore, when the relationship between the measured value and the reproduced value in the reactance component Z-Im is confirmed, it can be seen that there are characteristics as shown in FIG. 15. FIG. 15 is a diagram showing an example of characteristics of the reactance component in an equivalent reproduction circuit (equivalent reproduction circuit EC1) configured by the battery characteristic reproduction device 100 of the embodiment. In (a) of FIG. 15, frequency characteristics of a difference between the measured value and the reproduced value of the reactance component Z-Im (a difference reactance component ΔZ-Im) are shown. In (b) of FIG. 15, frequency characteristics of a reciprocal (=1/{(ΔZ-Im)*(ω}) of a value obtained by multiplying the difference reactance component ΔZ-Im by the angular frequency to are shown.

As shown in (a) of FIG. 15, a frequency characteristic value of the difference reactance component ΔZ-Im increases as the frequency decreases. In other words, the frequency characteristic of the difference reactance component ΔZ-Im is the characteristic of the difference between the measured value and the reproduced value of the reactance component Z-Im that increases as the frequency decreases. As shown in (b) of FIG. 15, the frequency characteristic of 1/{(ΔZ-Im)*ω} is generally close to a flat value at a frequency on a lower-frequency side than 0.1 [Hz]. Here, because the unit of the difference reactance component ΔZ-Im is Ohm ([Ω]), the unit of a reciprocal (=1/{(ΔZ-Im)*ω}) of a value obtained by multiplying the difference reactance component ΔZ-Im by the angular frequency ω corresponds to Farad ([F]). That is, the reciprocal of the value obtained by multiplying the difference reactance component ΔZ-Im by the angular frequency ω corresponds to capacitance (hereinafter referred to as “capacitance Cs”).

Therefore, the equivalent circuit configurator 108 configures an equivalent reproduction circuit in which the difference in the reactance component Z-Im generated on the low-frequency side is reduced (corrected) by connecting (inserting) a capacitor C0 having the capacitance Cs close to a nearly flat value in (b) of FIG. 15 in series with the equivalent reproduction circuit EC1 shown in (a) of FIG. 8. The low-frequency band extractor 104 may decide on the capacitance Cs of the capacitor C0 inserted here, for example, by extracting the reactance component Z-Im on the low-frequency side on the basis of the input battery characteristic data. For example, after the equivalent circuit configurator 108 temporarily configures the equivalent reproduction circuit EC1 as shown in (a) of FIG. 8, the capacitance Cs of the capacitor C0 may be determined by calculating the difference between the reactance component Z-Im (reproduced value) calculated using the equivalent reproduction circuit EC1 and the reactance component Z-Im (measured value) represented by the input battery characteristic data. At this time, the equivalent circuit configurator 108 may average values of parts close to flat values to decide on the capacitance Cs of the capacitor C0.

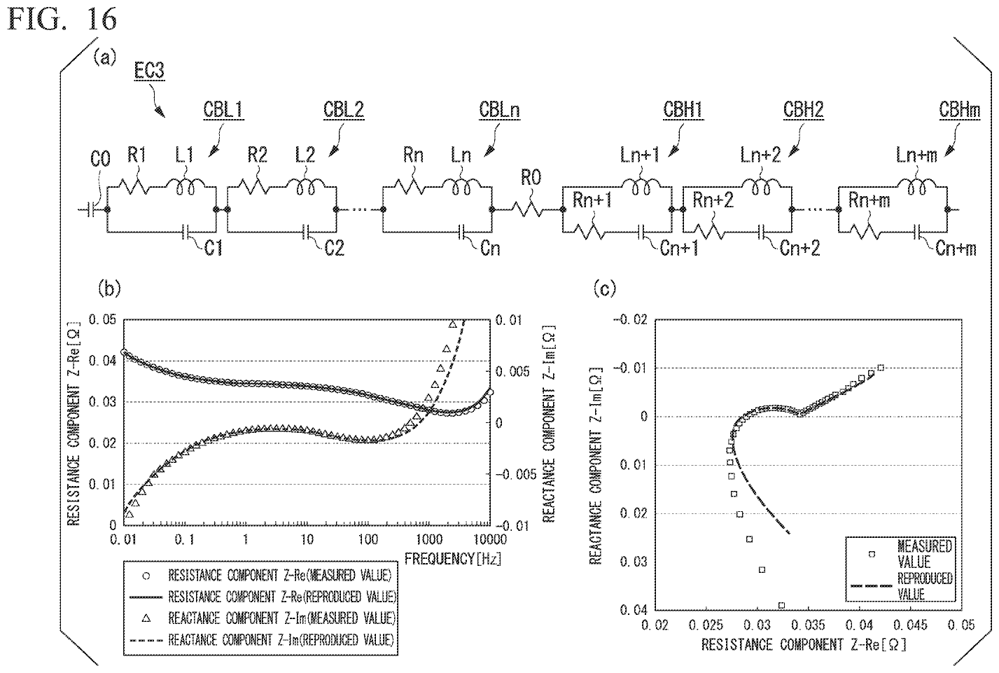

FIG. 16 is a diagram showing an example of a configuration of an equivalent reproduction circuit configured by the battery characteristic reproduction device 100 of the embodiment (an equivalent reproduction circuit of the third embodiment) and its characteristics. In (a) of FIG. 16, an example of an equivalent reproduction circuit (hereinafter referred to as an “equivalent reproduction circuit EC3”) configured by the battery characteristic reproduction device 100 (more specifically, the equivalent circuit configurator 108) is shown. (b) of FIG. 16 illustrates frequency characteristics shown by dividing the impedance |z| (absolute value) included in the impedance characteristics into a resistance component Z-Re (a real part) and a reactance component Z-Im (an imaginary part). (c) of FIG. 16 illustrates frequency characteristics shown in (b) of FIG. 16 by a Nyquist plot. In (b) of FIG. 16 and (c) of FIG. 16, as in (b) of FIG. 8 and (c) of FIG. 8, the measured value and the reproduced value (calculated value) of the impedance characteristic are also shown for a comparison. The characteristics of the measured values in (b) of FIG. 16 and (c) of FIG. 16 are the same as the characteristics shown in FIG. 2 as in (b) of FIG. 8 and (c) of FIG. 8.

In the equivalent reproduction circuit EC3 shown in (a) of FIG. 16, the capacitor C0 is connected in series with a stage previous to the circuit block CBL1 in the equivalent reproduction circuit EC1 of the first embodiment shown in (a) of FIG. 8. Also, in the equivalent reproduction circuit EC3, because the resistor R0, the plurality of circuit blocks CBL, the plurality of circuit blocks CBH, and the capacitor C0 are connected in series, the order in which constituent elements are connected does not affect the impedance characteristics of the battery to be reproduced.

When the impedance characteristics calculated using the equivalent reproduction circuit EC3 are compared with the frequency characteristics shown in (b) of FIG. 16, it can be seen that the resistance component Z-Re and the reactance component Z-Im generally match the measured value and the reproduced value at the frequency on the low-frequency side. On the other hand, when the impedance characteristics calculated using the equivalent reproduction circuit EC3 are compared with the Nyquist plot shown in (c) of FIG. 16, it can be seen that the difference between the measured value and the reproduced value on the low-frequency side, i.e., the difference caused in a Warburg resistance characteristic part, decreases and generally matches. As described above, it is considered that the difference between the measured value and the reproduced value on the high-frequency side in the Nyquist plot shown in (c) of FIG. 16 can be allowed to generally match by configuring an equivalent reproduction circuit similar to the equivalent reproduction circuit EC2 of the second embodiment as described above.

Thus, the battery characteristic reproduction device 100 can reproduce (calculate) impedance characteristics similar to impedance characteristics obtained by actually measuring a target battery constituting the equivalent reproduction circuit EC3 in the range of a frequency (a frequency at which the Warburg resistance characteristic appears) on the low-frequency side as described above by configuring the equivalent reproduction circuit EC3 as shown in (a) of FIG. 16 on the basis of the difference between the measured value and the reproduced value (calculated value) of the reactance component Z-Im generated on the low-frequency side (the difference in the part of the Warburg resistance characteristic). Moreover, the battery characteristic reproduction device 100 can configure the equivalent reproduction circuit EC3 only by performing a simple process of connecting (inserting) the capacitor C0 of the capacitance Cs based on the difference between the measured value and the reproduced value (calculated value) of the reactance component Z-Im in series. Thereby, it is possible to estimate various states inside of the battery with higher accuracy by calculating the response, behavior, and the like when a current is applied to the battery using the equivalent reproduction circuit EC3 configured by the battery characteristic reproduction device 100.

### Fourth Embodiment

Next, in the impedance characteristics calculated using the equivalent reproduction circuit EC1 of the first embodiment configured by the battery characteristic reproduction device 100, an example of a method of configuring an equivalent reproduction circuit including both reduction (correction) of the difference in the reactance component Z-Im generated on the high-frequency side in the second embodiment and reduction (correction) of the difference in the reactance component Z-Im generated on the low-frequency side in the third embodiment will be described as the fourth embodiment.

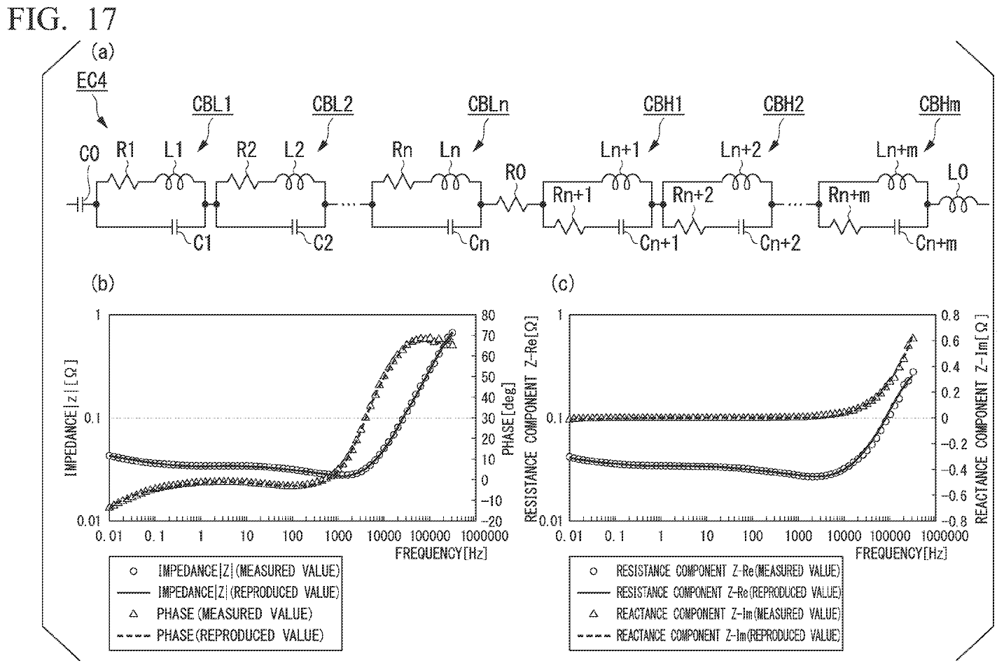

FIG. 17 is a diagram showing an example of a configuration of an equivalent reproduction circuit (an equivalent reproduction circuit of the fourth embodiment) configured by the battery characteristic reproduction device 100 of the embodiment and its characteristics. In (a) of FIG. 17, an example of an equivalent reproduction circuit (hereinafter referred to as an “equivalent reproduction circuit EC4”) configured by the battery characteristic reproduction device 100 (more specifically, the equivalent circuit configurator 108) is shown. (b) of FIG. 17 shows the impedance |z| (absolute value) included in the impedance characteristic and the phase in a Bode plot. (c) of FIG. 17 illustrates frequency characteristics shown by dividing data identical to impedance |z| shown in (b) of FIG. 17 into a resistance component Z-Re (a real part) and a reactance component Z-Im (an imaginary part). As in (b) of FIG. 8 and (c) of FIG. 8, the measured value and the reproduced value (calculated value) of the impedance characteristic are also shown for a comparison in (b) of FIG. 17 and (c) of FIG. 17. The characteristics of the measured values in (b) of FIG. 17 and (c) of FIG. 17 are the same as the characteristics shown in FIG. 2 as in (b) of FIG. 8 and (c) of FIG. 8.

In the equivalent reproduction circuit EC4 shown in (a) of FIG. 17, as in the equivalent reproduction circuit EC2 of the second embodiment, the inductor L0 is connected in series with a stage subsequent to the circuit block CBHm in the equivalent reproduction circuit EC1 of the first embodiment shown in (a) of FIG. 8, and as in the equivalent reproduction circuit EC3 of the third embodiment, the capacitor C0 is connected in series with a stage previous to the circuit block CBL1 in the equivalent reproduction circuit EC1 of the first embodiment shown in (a) of FIG. 8. Because the equivalent reproduction circuit EC4 also has a configuration in which the resistor R0, a plurality of circuit blocks CBL, a plurality of circuit blocks CBH, an inductor L0, and a capacitor C0 are connected in series, the order in which constituent elements are connected does not affect the impedance characteristics of the battery to be reproduced.

When the impedance characteristics calculated using the equivalent reproduction circuit EC4 are compared with the Bode plot shown in (b) of FIG. 17, it can be seen that the impedance |z| and the phase generally match the measured value and the reproduced value at all frequencies. On the other hand, when the impedance characteristics calculated using the equivalent reproduction circuit EC4 are compared with the frequency characteristics shown in (c) of FIG. 17, it can be seen that the resistance component Z-Re and the reactance component Z-Im generally match the measured value and the reproduced value at all frequencies.

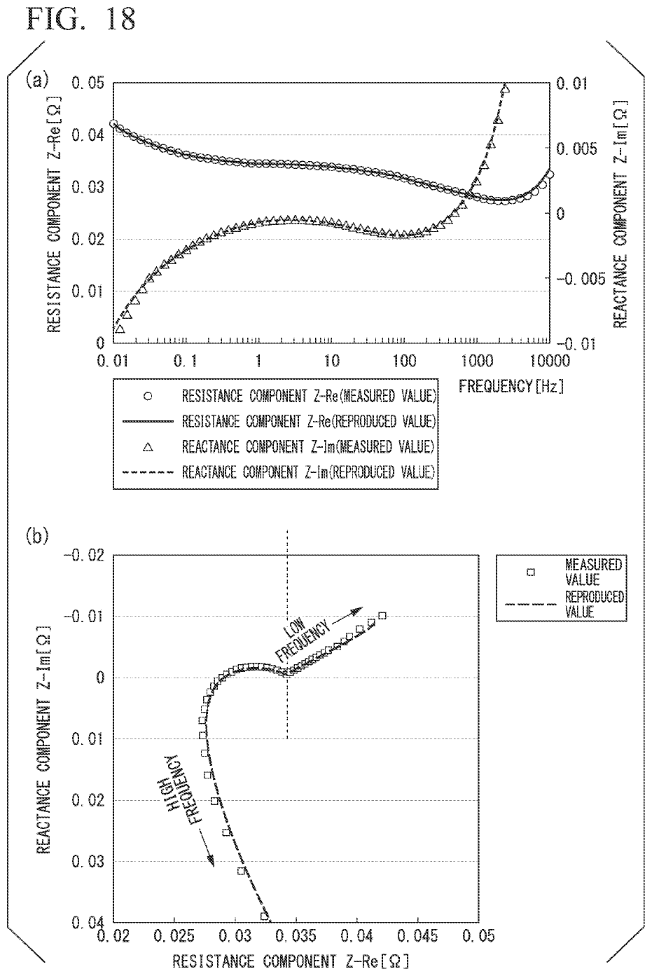

Here, a matching degree on the low-frequency side in the impedance characteristics calculated using the equivalent reproduction circuit EC4 will be described. FIG. 18 is a diagram showing an example of a matching degree of the impedance characteristics of the equivalent reproduction circuit (the equivalent reproduction circuit EC4) configured by the battery characteristic reproduction device 100 of the embodiment. (a) of FIG. 18 illustrates frequency characteristics shown by dividing each of a measured value of the measured impedance |z| (absolute value) represented by the measured impedance characteristic and a reproduced value (a calculated value) of the impedance |z| (absolute value) represented by the impedance characteristic calculated (simulated) using the equivalent reproduction circuit EC4 into a resistance component Z-Re (a real part) and a reactance component Z-Im (an imaginary part). As in the third embodiment described with reference to (a) of FIG. 14, (a) of FIG. 18 is an enlarged version of the low-frequency side (a range up to 10 [kHz]) in the frequency characteristics shown in (c) of FIG. 17. (b) of FIG. 18 illustrates frequency characteristics shown in (a) of FIG. 18 by a Nyquist plot.

As can be seen from the frequency characteristics shown in (a) of FIG. 18, it can be seen that the resistance component Z-Re and the reactance component Z-Im generally match the measured value and the reproduced value at all frequencies. Furthermore, looking at the Nyquist plot shown in (b) of FIG. 18, it can also be seen that the measured value and the reproduced value generally match at all frequencies in a state in which a Warburg resistance characteristic part is included.

Thus, the battery characteristic reproduction device 100 can reproduce (calculate) impedance characteristics similar to impedance characteristics obtained by actually measuring the target battery constituting the equivalent reproduction circuit EC4 in the range of almost all frequencies as described above by configuring the equivalent reproduction circuit EC4 as shown in (a) of FIG. 17 on the basis of the difference between the measured value and the reproduced value (calculated value) of the reactance component Z-Im generated on the high-frequency side and the low-frequency side. Moreover, in the battery characteristic reproduction device 100, as in the equivalent reproduction circuit EC2 of the second embodiment and the equivalent reproduction circuit EC3 of the third embodiment, it is possible to configure the equivalent reproduction circuit EC4 having high reproducibility in a wider frequency range only by performing a simple process of making a series connection (insertion) of the inductor L0 of the inductance Ls and the capacitor C0 of the capacitance Cs based on the difference between the measured value and the reproduced value (calculated value) of the reactance component Z-Im. Thereby, various states inside of the battery can be further estimated with high accuracy by calculating the response, behavior, and the like when a current is applied to the battery using the equivalent reproduction circuit EC4 configured by the battery characteristic reproduction device 100.

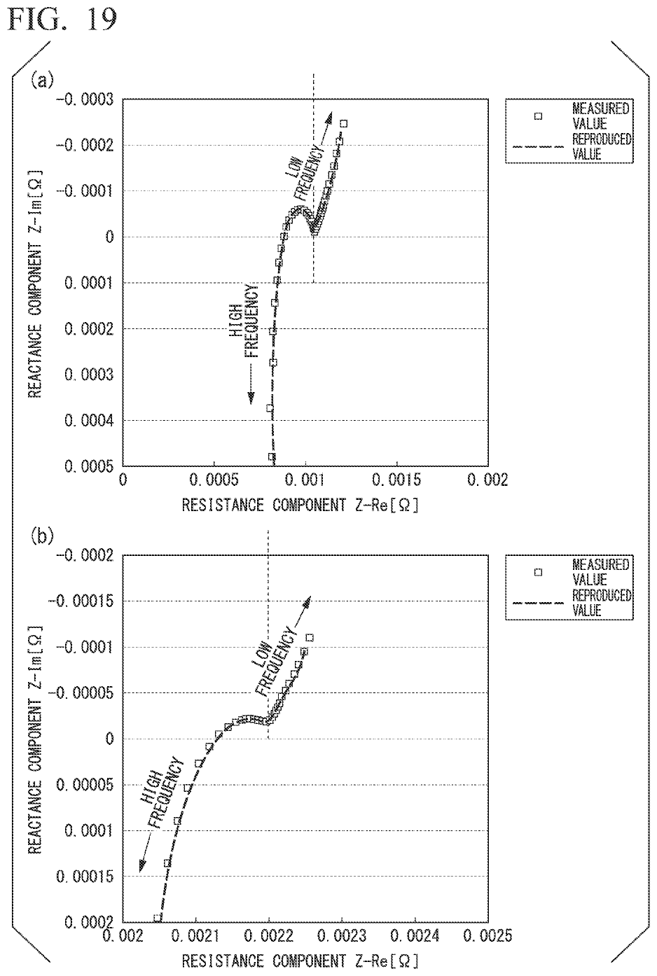

Here, an example in which the battery characteristic reproduction device 100 configures an equivalent reproduction circuit EC4 when battery characteristic data of batteries having different configurations is input will be described. FIG. 19 is a diagram showing an example of the impedance characteristics of an equivalent reproduction circuit (equivalent reproduction circuit EC4) configured by the battery characteristic reproduction device 100 of the embodiment. In the example shown in FIG. 19, the battery characteristic reproduction device 100 represents frequency characteristics obtained by dividing the impedance |z| included in impedance characteristics when the equivalent reproduction circuit EC4 corresponding to two types of batteries with different configurations is configured into the resistance component Z-Re (real part) and the reactance component Z-Im (imaginary part) by a Nyquist plot. The impedance characteristics shown in (a) of FIG. 19 are represented by, for example, a Nyquist plot of a pouch-type battery in which battery cells are laminated with a film. The impedance characteristics shown in (b) of FIG. 19 are represented by, for example, a Nyquist plot of a rectangular battery.

As can be seen from each of the Nyquist plots shown in (a) of FIG. 19 and (b) of FIG. 19, in the equivalent reproduction circuit EC4 configured by the battery characteristic reproduction device 100, the measured value and the reproduced value generally match at all frequencies in a state in which the Warburg resistance characteristic part is included regardless of the battery configuration. That is, it can be seen that the battery characteristic reproduction device 100 can accurately reproduce the impedance characteristics represented by the input battery characteristic data regardless of the battery configuration.

### Detailed Configuration of Equivalent Reproduction Circuit

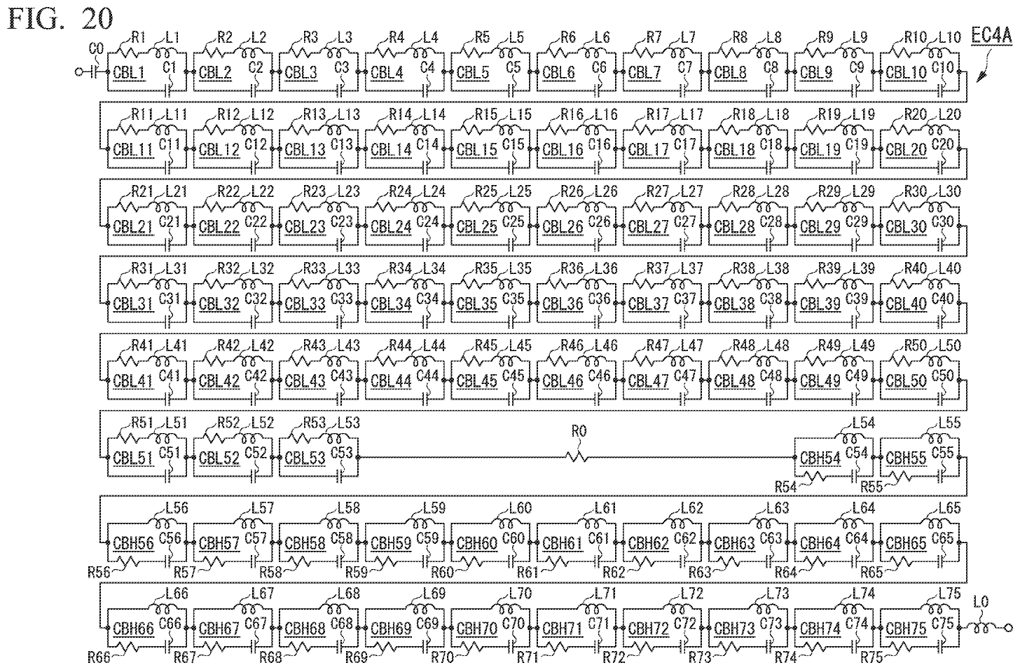

Next, a more detailed configuration of the equivalent reproduction circuit EC4 will be described. FIG. 20 is a diagram showing an example of a more detailed configuration of an equivalent reproduction circuit (the equivalent reproduction circuit EC4) configured by the battery characteristic reproduction device 100 of the embodiment. In the equivalent reproduction circuit EC4 (hereinafter referred to as an “equivalent reproduction circuit EC4A”) shown in FIG. 20, a capacitor C0, 53 circuit blocks CBL (circuit blocks CBL1 to CBL53), a resistor R0, 22 circuit blocks CBH (circuit blocks CBH54 to CBH75), and an inductor L0 are connected in series in that order.

As described above, in the equivalent reproduction circuit EC4A shown in FIG. the resistor R0 is an equivalent circuit provided in correspondence with the resistance value Rs of the minimum measurement point, each circuit block CBL is an equivalent circuit provided in correspondence with a measurement point located on the lower-frequency side than the minimum measurement point, and each circuit block CBH is an equivalent circuit provided in correspondence with a measurement point located on the higher-frequency side than the minimum measurement point. Thus, at least an equivalent circuit corresponding to each measurement point is provided in the battery characteristic reproduction device 100. Furthermore, in the equivalent reproduction circuit EC4A shown in FIG. 20, the capacitor C0 is an equivalent circuit provided to correct the impedance characteristics on the low-frequency side and the inductor L0 is an equivalent circuit provided to correct the impedance characteristics on the high-frequency side. Thus, in the battery characteristic reproduction device 100, an equivalent circuit for correcting the impedance characteristics of one or both of the low-frequency side and the high-frequency side is provided. Because the equivalent reproduction circuit EC4A also has a configuration in which the resistor R0, 53 circuit blocks CBL, 22 circuit blocks CBH, an inductor L0, and a capacitor C0 are connected in series, the order in which the constituent elements are connected does not affect the impedance characteristics of the battery to be reproduced.

### Example of Process of Battery Characteristic Reproduction Device

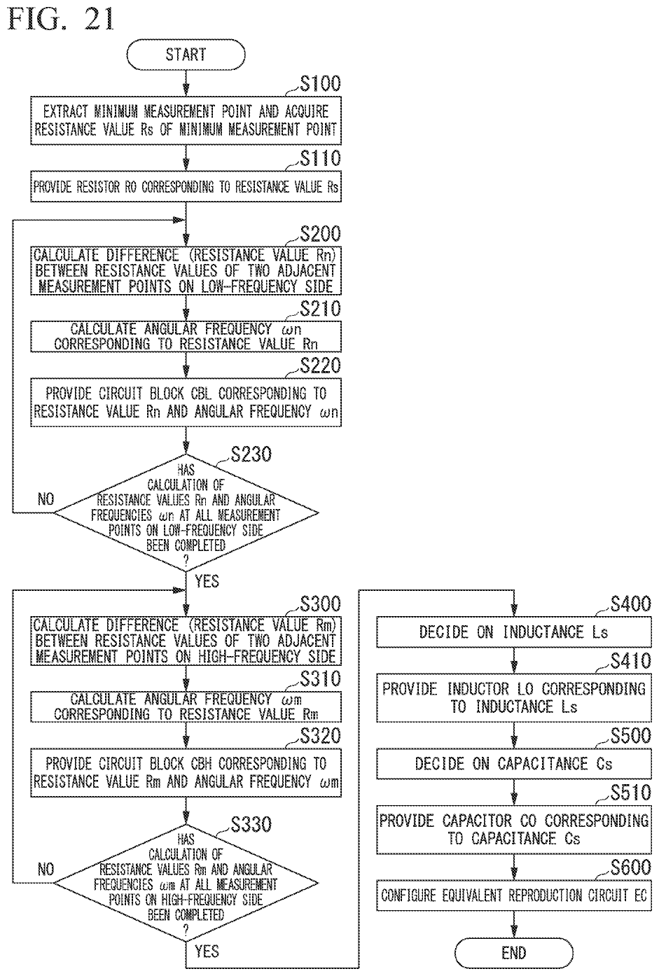

Here, an example of a process of configuring an equivalent reproduction circuit in the battery characteristic reproduction device 100 will be described. FIG. 21 is a flowchart showing an example of a flow of a process executed when an equivalent reproduction circuit EC is configured in the battery characteristic reproduction device 100 of the embodiment. In the following description, a case in which the equivalent reproduction circuit EC4A is configured in the battery characteristic reproduction device 100 will be described.

When battery characteristic data is input to the battery characteristic reproduction device 100, the smallest value extractor 102 extracts a minimum measurement point and acquires a resistance value of the extracted minimum measurement point (a minimum resistance value) as a resistor Ra (step S100). The smallest value extractor 102 outputs an acquired resistance value Rs and an angular frequency ω0 of the extracted minimum measurement point to the equivalent circuit configurator 108. Thereby, the equivalent circuit configurator 108 provides a resistor R0 corresponding to the resistance value Rs output by the smallest value extractor 102 (step S110).

The low-frequency band extractor 104 acquires resistance values of the two adjacent measurement points on the lower-frequency side than the minimum measurement point and calculates the difference (a resistance value Rn) of the two acquired resistance values (step S200). Further, the low-frequency band extractor 104 calculates an angular frequency ωn corresponding to the resistance value Rn (step S210). The low-frequency band extractor 104 outputs the calculated resistance value Rn and the calculated angular frequency ωn to the equivalent circuit configurator 108. Thereby, the equivalent circuit configurator 108 provides a circuit block CBL corresponding to the resistance value Rn and the angular frequency ωn output by the low-frequency band extractor 104 (step S220). The low-frequency band extractor 104 determines whether or not the calculation of the resistance value Rn and the angular frequency ωn corresponding to all the measurement points located on the lower-frequency side than the minimum measurement point has been completed (step S230). In step S230, when it is determined that the calculation of the resistance value Rn and the angular frequency ωn corresponding to all measurement points located on the lower-frequency side than the minimum measurement point has not been completed, the low-frequency band extractor 104 returns the process to step S200.

On the other hand, in step S230, when it is determined that the calculation of the resistance value Rn and the angular frequency ωn corresponding to all the measurement points located on the lower-frequency side than the minimum measurement point has been completed, the high-frequency band extractor 106 acquires resistance values of two adjacent measurement points on the higher-frequency side than the minimum measurement point and calculates the difference (a resistance value Rm) between the two acquired resistance values (step S300). Further, the high-frequency band extractor 106 calculates an angular frequency ωm corresponding to the resistance value Rm (step S310). The high-frequency band extractor 106 outputs the calculated resistance value Rm and the calculated angular frequency ωm to the equivalent circuit configurator 108. Thereby, the equivalent circuit configurator 108 provides a circuit block CBH corresponding to the resistance value Rm and the angular frequency ωm output by the high-frequency band extractor 106 (step S320). Subsequently, the high-frequency band extractor 106 determines whether or not the calculation of the resistance value Rm and the angular frequency ωm corresponding to all the measurement points located on the higher-frequency side than the minimum measurement point has been completed (step S330). In step S330, when it is determined that the calculation of the resistance value Rm and the angular frequency ωm corresponding to all the measurement points located on the higher-frequency side than the minimum measurement point has not been completed, the high-frequency band extractor 106 returns the process to step S300. On the other hand, in step S330, when it is determined that the calculation of the resistance value Rm and the angular frequency ωm corresponding to all the measurement points located on the higher-frequency side than the minimum measurement point has been completed, the high-frequency band extractor 106 (or the equivalent circuit configurator 108) decides on the inductance Ls (step S400). Subsequently, the equivalent circuit configurator 108 provides an inductor L0 corresponding to the determined inductance Ls (step S410).

The low-frequency band extractor 104 (or the equivalent circuit configurator 108) decides on capacitance Cs (step S500). Also, the equivalent circuit configurator 108 provides a capacitor C0 corresponding to the determined capacitance Cs (step S510).

Subsequently, the equivalent circuit configurator 108 connects the provided constituent elements in series to configure the equivalent reproduction circuit EC4A (step S600). Also, the battery characteristic reproduction device 100 ends the process of the present flowchart for configuring the equivalent reproduction circuit EC4A.

In this process, the battery characteristic reproduction device 100 configures the equivalent reproduction circuit EC4A. A case where the smallest value extractor 102, the low-frequency band extractor 104, and the high-frequency band extractor 106 perform a sequential process has been described with reference to the flowchart shown in FIG. 21. However, in the battery characteristic reproduction device 100, after the process of extracting the minimum measurement point (the processing of step S100) is completed by the smallest value extractor 102, the low-frequency band extractor 104 and the high-frequency band extractor 106 (or the equivalent circuit configurator 108) may start their own processes to be executed at the same time. That is, in the battery characteristic reproduction device 100, the processing of steps S200 to S230 in the low-frequency band extractor 104 (and the equivalent circuit configurator 108) and the processing of steps S300 to S330 in the high-frequency band extractor 106 (and equivalent circuit configurator 108) may be executed at the same time. Further, in the battery characteristic reproduction device 100, the low-frequency band extractor 104, the high-frequency band extractor 106, and the equivalent circuit configurator 108 may simultaneously execute corresponding processes in the processing of steps S400 to S600.

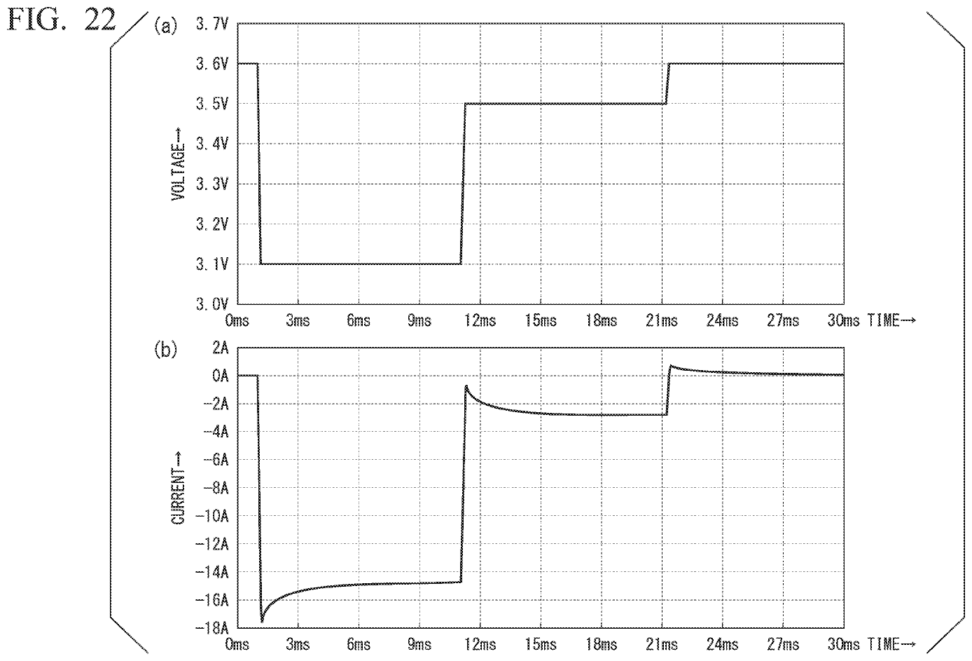

Thereby, various states inside of the battery can be further estimated with high accuracy by calculating the response, behavior, and the like when a current is applied to the battery using the equivalent reproduction circuit EC4A configured by the battery characteristic reproduction device 100. Here, an example of a case where a response of a battery is calculated using the equivalent reproduction circuit EC4A will be described. FIG. 22 is a diagram showing an example of a case where a response of a battery is calculated using an equivalent reproduction circuit (the equivalent reproduction circuit EC4A) configured by the battery characteristic reproduction device 100 of the embodiment. FIG. 22 is an example in which a response of a current is calculated when a prescribed voltage waveform is applied to the battery. In (a) of FIG. 22, an example of a voltage waveform given (input) to the equivalent reproduction circuit EC4A is shown. In (b) of FIG. 22, an example of a current response (a current waveform) calculated by the equivalent reproduction circuit EC4A in accordance with the input voltage waveform of (a) of FIG. 22 is shown. In (b) of FIG. 22, it is possible to estimate that nonlinear characteristics such as overshoot and undershoot appear in a current waveform. Thus, it is possible to estimate a response of a battery with high accuracy using the equivalent reproduction circuit EC4A configured by the battery characteristic reproduction device 100.

As described above, according to the battery characteristic reproduction device 100 of the embodiment, for example, the smallest value extractor 102, the low-frequency band extractor 104, the high-frequency band extractor 106, and the equivalent circuit configurator 108 are provided. Also, in the battery characteristic reproduction device 100 of the embodiment, the smallest value extractor 102 extracts a minimum measurement point on the basis of input battery characteristic data and outputs the resistance value Rs that is the center of the impedance characteristic to be reproduced and information indicating the extracted minimum measurement point (for example, an angular frequency ω₀) to the equivalent circuit configurator 108. Furthermore, in the battery characteristic reproduction device 100 of the embodiment, the low-frequency band extractor 104 calculates the difference (a resistance value Rn) between resistance values of two adjacent measurement points located on a lower-frequency side than the minimum measurement point and a corresponding angular frequency ωn for each measurement point on the basis of the input battery characteristic data and outputs the difference and the corresponding angular frequency ωn to the equivalent circuit configurator 108. Furthermore, in the battery characteristic reproduction device 100 of the embodiment, the high-frequency band extractor 106 calculates the difference (a resistance value Rm) between resistance values of two adjacent measurement points located on a higher-frequency side than the minimum measurement point and a corresponding angular frequency ωm for each measurement point on the basis of the input battery characteristic data and outputs the difference and the corresponding angular frequency ωm to the equivalent circuit configurator 108. In the battery characteristic reproduction device 100 of the embodiment, the equivalent circuit configurator 108 configures an equivalent reproduction circuit by connecting a plurality of constituent elements (equivalent circuits) based on the resistance value Rs output by the smallest value extractor 102, the resistance value Rn and the angular frequency ωn output by the low-frequency band extractor 104, and the resistance value Rm and the angular frequency ωm output by the high-frequency band extractor 106 in series. Furthermore, in the battery characteristic reproduction device 100 of the embodiment, the high-frequency band extractor 106 (or the equivalent circuit configurator 108) decides on the inductance Ls for reducing (correcting) the difference in the reactance component Z-Im generated on the high-frequency side and the low-frequency band extractor 104 (or the equivalent circuit configurator 108) decides on the capacitance Cs for reducing (correcting) the difference in the reactance component Z-Im generated on the low-frequency side. In the battery characteristic reproduction device 100 of the embodiment, the equivalent circuit configurator 108 configures an equivalent reproduction circuit by connecting constituent elements (equivalent circuits) based on the determined inductance Ls and/or capacitance Cs in series. Thus, in the battery characteristic reproduction device 100 of the embodiment, an equivalent reproduction circuit for accurately reproducing the impedance characteristics of the battery indicated in the input battery characteristic data can be configured only by performing a simple process. Thereby, it is possible to calculate the response, behavior, and the like when a current is applied to the battery by setting prescribed parameters of the equivalent reproduction circuit configured by the battery characteristic reproduction device 100 of the embodiment. Thereby, it is possible to estimate various states inside of the battery with high accuracy using the equivalent reproduction circuit configured by the battery characteristic reproduction device 100 of the embodiment. For example, when a battery is mounted in a vehicle such as an electric vehicle, it is possible to derive a preferred current-carrying pattern that is within an upper limit value and a lower limit value of a voltage of the battery by setting a parameter representing the current-carrying pattern when an electric motor is driven in an equivalent reproduction circuit configured by the battery characteristic reproduction device 100 of the embodiment.

The battery characteristic reproduction device 100 of the embodiment described above includes: the smallest value extractor 102 configured to extract a smallest resistance value Rs included in frequency characteristics of measured impedance of a battery; the difference extractor (the low-frequency band extractor 104 and the high-frequency band extractor 106) configured to extract the difference between a resistance value measured at a measurement point and a resistance value measured at an adjacent measurement point for each measurement point of each frequency included in the frequency characteristics; and the equivalent circuit configurator 108 configured to reproduce the frequency characteristics of the impedance in the battery by configuring the smallest resistance value Rs extracted by the smallest value extractor 102 as a first resistance component (the resistor R0), configuring an equivalent circuit (the circuit block CBL and the circuit block CBH) of the battery including the difference between the resistance values extracted by the difference extractor as a second resistance component (the resistor R) for each measurement point, and connecting the resistor R0 and the equivalent circuit for each measurement point in series, whereby it is possible to configure an equivalent reproduction circuit for reproducing characteristics of a battery on the basis of measured impedance characteristics of the battery. From these, it is expected to contribute to improving energy efficiency in the battery and reducing adverse effects on the global environment using an equivalent reproduction circuit configured by the battery characteristic reproduction device 100 of the embodiment.

The embodiment described above can be represented as follows.

A battery characteristic reproduction device including:
a hardware processor; and
a storage device storing a program,
wherein the hardware processor reads and executes the program stored in the storage device to:
extract a smallest resistance value included in frequency characteristics of measured impedance of a battery;
extract the difference between a resistance value measured at a measurement point and a resistance value measured at an adjacent measurement point for each measurement point of each frequency included in the frequency characteristics; and
reproduce the frequency characteristics of the impedance in the battery by configuring the extracted smallest resistance value as a first resistance component, configuring an equivalent circuit of the battery including the extracted difference between the resistance values as a second resistance component for each measurement point, and connecting the first resistance component and the equivalent circuit for each measurement point in series.

Although modes for carrying out the present invention have been described above using embodiments, the present invention is not limited to the embodiments and various modifications and substitutions can be made without departing from the scope and spirit of the present invention.

What is claimed is:

1. A battery characteristic reproduction device comprising a processor configured to execute computer-readable instructions to perform:
extracting a smallest resistance value included in frequency characteristics of measured impedance of a battery;
extracting a difference between a resistance value measured at a measurement point and a resistance value measured at an adjacent measurement point for each measurement point of each frequency included in the frequency characteristics; and
reproducing the frequency characteristics of the impedance in the battery by configuring the smallest resistance value extracted as a first resistance component, configuring an equivalent circuit of the battery including the difference between the resistance values extracted as a second resistance component for each measurement point, and connecting the first resistance component and the equivalent circuit for each measurement point in series.

2. The battery characteristic reproduction device according to claim 1,
wherein the extracting the difference between the resistance values comprises:
extracting the difference between the resistance values in a band of a frequency lower than a frequency of a measurement point at which the smallest resistance value has been extracted, and
extracting the difference between the resistance values in a band of a frequency higher than the frequency of the measurement point at which the smallest resistance value has been extracted, and
wherein the reproducing the frequency characteristics of the impedance in the battery comprises:
making the equivalent circuit including the difference between the resistance values extracted by the low-frequency band as the second resistance component different from the equivalent circuit including the difference between the resistance values extracted by the high-frequency band as the second resistance component.

3. The battery characteristic reproduction device according to claim 2,
wherein the equivalent circuit including the difference between the resistance values extracted by the low-frequency band as the second resistance component has a configuration in which a series circuit in which the second resistance component is connected in series with an impedance component representing a frequency of the measurement point is connected in parallel to a capacitance component representing the frequency of the measurement point, and
wherein the equivalent circuit including the difference between the resistance values extracted by the high-frequency band as the second resistance component has a configuration in which a series circuit in which the second resistance component is connected in series with the capacitance component representing the frequency of the measurement point is connected in parallel to the impedance component representing the frequency of the measurement point.

4. The battery characteristic reproduction device according to claim 3,
wherein the processor is configured to execute the computer-readable instructions to perform:
extracting a high-frequency-side reactance component in the battery included in the frequency characteristics, and
reproducing the frequency characteristics of the impedance in the battery by further connecting an inductor having inductance representing the high-frequency-side reactance component in series.

5. The battery characteristic reproduction device according to claim 3,
wherein the processor is configured to execute the computer-readable instructions to perform:
extracting a low-frequency-side reactance component in the battery included in the frequency characteristics, and
reproducing the frequency characteristics of the impedance in the battery by further connecting a capacitor having capacitance representing the low-frequency-side reactance component in series.

6. A battery characteristic reproduction method comprising:
extracting, by a computer, a smallest resistance value included in frequency characteristics of measured impedance of a battery;
extracting, by the computer, a difference between a resistance value measured at a measurement point and a resistance value measured at an adjacent measurement point for each measurement point of each frequency included in the frequency characteristics; and
reproducing, by the computer, the frequency characteristics of the impedance in the battery by configuring the extracted smallest resistance value as a first resistance component, configuring an equivalent circuit of the battery including the extracted difference between the resistance values as a second resistance component for each measurement point, and connecting the first resistance component and the equivalent circuit for each measurement point in series.

7. A non-transitory computer-readable storage medium storing a program for causing a computer to:
extract a smallest resistance value included in frequency characteristics of measured impedance of a battery;
extract a difference between a resistance value measured at a measurement point and a resistance value measured at an adjacent measurement point for each measurement point of each frequency included in the frequency characteristics; and
reproduce the frequency characteristics of the impedance in the battery by configuring the extracted smallest resistance value as a first resistance component, configuring an equivalent circuit of the battery including the extracted difference between the resistance values as a second resistance component for each measurement point, and connecting the first resistance component and the equivalent circuit for each measurement point in series.
